(19) United States
(12) Patent Application Publication
(10) Pub. No.: US 2024/0313144 A1
(43) Pub. Date: Sep. 19, 2024

(54) APPARATUS, METHOD AND SYSTEM FOR ABSORBING ELECTROMAGNETIC RADIATION, AND METHOD FOR MANUFACTURING AN APPARATUS FOR ABSORBING ELECTROMAGNETIC RADIATION

(71) Applicants: Fraunhofer-Gesellschaft zur Förderung der angewandten Forschung e.V., München (DE); Brandenburgische Technische Universitat (BTU) Cottbus-Senftenberg,Körperschaft des öffentlichen Rech, Cottbus (DE)

(72) Inventors: Jens KNOBBE, Dresden (DE); Lion AUGEL, Dresden (DE)

(21) Appl. No.: 18/679,606

(22) Filed: May 31, 2024

Related U.S. Application Data
(63) Continuation of application No. PCT/EP2022/083869, filed on Nov. 30, 2022.

(30) Foreign Application Priority Data
Dec. 2, 2021 (DE) 10 2021 213 746.6

(51) Int. Cl. H01L 31/108; H01L 29/872; H01L 31/02; H01L 31/054; H01L 33/00

(52) U.S. Cl. CPC H01L 31/108; H01L 29/872; H01L 31/02005; H01L 31/0547; H01L 33/005

(57) ABSTRACT

An apparatus for absorbing electromagnetic radiation, including: a substrate with a main side and a beam guiding unit arranged on the main side of the substrate, wherein the beam guiding unit includes a semiconductor material and wherein the semiconductor material is transparent for the electromagnetic radiation. The beam guiding unit includes a first and a second portion, wherein the first portion is arranged between the substrate and the second portion. A cross-sectional area of the beam guiding unit in parallel to the main side of the substrate decreases with increasing distance to the main side more strongly in the second portion than in the first portion. The apparatus also includes a metal material, wherein the metal material is arranged at the second portion of the beam guiding unit on a side of the second portion facing away from the substrate, the metal material providing a Schottky junction.

### CROSS-REFERENCES TO RELATED APPLICATIONS

This application is a continuation of copending International Application No. PCT/EP2022/083869, filed Nov. 30, 2022, which is incorporated herein by reference in its entirety, and additionally claims priority from German Application No. DE 10 2021 213 746.6, filed Dec. 2, 2021, which is incorporated herein by reference in its entirety.

Embodiments of the present invention include apparatuses, methods and systems for absorbing electromagnetic radiation, and methods for manufacturing apparatuses for absorbing electromagnetic radiation. The present invention further relates to photodiodes with conical structure elements.

Embodiments of the present invention include conical photodiodes.

Embodiments of the present invention are in the field of semiconductor elements, in particular in the field of photodiodes.

Embodiments according to the present invention concern photodiodes for detecting electromagnetic radiation with wavelengths larger than approximately 1000 nm.

### BACKGROUND OF THE INVENTION

Among other things, problems that may be addressed with embodiments of the invention are described in the following.

Photodiodes may be used to detect electromagnetic radiation. The radiation is converted in the device into an electrically measurable photocurrent. In this case, the sensitivity of a photodiode depends, among other things, on the wavelength of the radiation to be detected. In addition to the type of the semiconductor material used, such as silicon or gallium arsenide (GaAs), the design determines the performance of a photodiode (e.g. pin diodes or Schottky-Diodes). However, all photodiodes have in common the excitation of electric charge carriers in the semiconductor, which can be measured as a photocurrent.

The wavelength range of electromagnetic radiation that can be detected by a photodiode is essentially determined by the semiconductor material. Silicon diodes can be used to detect radiation in the visible range and the immediately adjacent infrared range up to a boundary wavelength of approximately 1100 nm. Beyond that, germanium or standard indium gallium arsenide (InGaAs) is used as a detector material up to a boundary wavelength of 1700 nm. The wavelength range can be extended to up to 2500 nm with InGaAs alloys with a high proportion of indium.

The range between 1000 and 2500 nm is very important for various applications. The field of telecommunication uses wavelengths of around 1300 nm or 1550 nm. Absorption bands of some important molecules that are of great significance to spectral analytics are located in the so-called near infrared spectral range (NIR) between 1000 and 2500 nm. Important applications in this spectral range can also be found in the field of field monitoring with lasers.

As stated above, silicon cannot be used in a conventionally configured diode design due to its lack of sensitivity in NIR. The semiconductor material InGaAs used instead is an excellent physical-technical detector material with high sensitivity, but it also has significant disadvantages (cf. “prior art”).

In other words, electromagnetic radiation in the infrared range above a wavelength of 1.1 μm cannot be efficiently detected by silicon photodetectors that operate on the principle of fundamental absorption. Photodetectors for this wavelength range using compatible technology therefore use the principle of internal photoemission. In this case, incident radiation generates charge carriers at a metal-semiconductor junction. However, such detectors have disadvantages with respect to the generated dark currents, furthermore, the junction represents a mirror for the incident radiation in the planar design of the device. While the first characteristic is disadvantageous due to an increase of noise of such a device, the second characteristic reduces the signal strength in the device since the incident radiation is reflected and therefore not absorbed. The first characteristic is caused by imperfections along the metal-semiconductor junction and scales with the surface area, the second characteristic (reflections) can be reduced through appropriate structures. This results in an opposing dependency, since surfaces that disperse more strongly (rough surfaces) go along with an increased metalized surface area.

For more details, prior art photodiodes of different designs are described in the following.

Photodiodes of different designs are well known in the prior art, and the underlying mechanisms of converting electromagnetic radiation in electric charge carriers in a semiconductor are well understood. The following particularly describes known devices for detecting radiation with wavelengths of more than approximately 1000 nm, together with the particularities prevailing in this wavelength range. The prior art differentiates between three large groups of known device concepts.

The p-i-n diode, or pin diode in short, is the design that is used most often. This is a layer sequence of doped and undoped areas in the semiconductor. The letters indicate the type of doping, i.e. the type of the majority charge carriers in the corresponding layer, p stands for holes, n stands for electrons, i stands for intrinsic, i.e. without doping. The conversion of radiation into a measurable photocurrent takes place in such a diode by means of the so-called photo effect. In this case, a photon is absorbed in the semiconductor, in particular in the intrinsic layer, and an electron is excited out of the valence band into the conduction band. Together with the created hole in the valence band, a charge carrier pair that is separated in the internal electric field between the layers and that can be detected as a photocurrent is formed. This basic principle is used for the prevalent semiconductors of silicon, germanium, and different alloys in the field of compound semiconductors of main groups III and V in the periodic table of elements, so-called III/V semiconductors.

Sometimes alloys of main groups II and VI, so-called II/VI semiconductors, such as e.g. mercury cadmium telluride (HgCdTe) are used. In particular, InGaAs is an advantageous semiconductor material for NIR.

However, the above-described functionality is only ensured up to a certain boundary wavelength of the radiation to be detected, or the relevant energy of the associated photons. For wavelengths above this boundary and energies below this boundary, no electrons may be excited in principle. Through this, the diode becomes insensitive in this wavelength range. In this case, the boundary energy is a characteristic of the semiconductor used (the so-called band gap between the valence band and the conduction band). For element semiconductors such as silicon, the band gap is specified, for compound semiconductors, it may be set within certain limits by changing the alloy proportions of the elements involved. For silicon, this limit is at approximately 1100 nm, for germanium it is at approximately 1700 nm.

Due to the above-mentioned reasons, pin diodes covering the range of 1000 nm to 2500 nm can only be realized with compound semiconductors. The most important semiconductor in this range is InGaAs with different alloys of a varying indium proportion. InGaAs pin diodes are characterized by a high sensitivity and are commercially available in many different designs. The greatest disadvantage of this material system is the non-compatibility with respect to the silicon technology. This results in relatively high costs for manufacturing the semiconductor material itself and for the process technology for realizing the devices. Furthermore, only a hybrid integration is possible in connection with integrated circuits usually manufactured using silicon technology. This also has a negative effect on the cost structure. Through this, many possible applications, in particular in the imaging field with diode arrays, can currently not be addressed or developed in an economically sensible way.

A further disadvantage is the use of the heavy metal arsenic in the InGaAs alloys. Since matters of sustainability will play a major role in the future, silicon technology has clear advantages.

Photoresistors form the second group of photodetectors in NIR. These devices change their resistance when being irradiated with electromagnetic radiation. Based on this characteristic, a photocurrent can also be measured. These devices are not diodes and therefore do not precisely belong directly to the prior art, however, they form an important group of photodetectors in NIR. Lead selenide and lead sulphide are often used as a material. Different designs, e.g. individual elements and line arrays, of these photodetectors are also commercially available. The disadvantages of this technology are similar to that of III/V semiconductors. The technology is not compatible with the silicon technology and contains lead as a heavy metal. In addition, there are also technical disadvantages. Photoresistors are comparably slow and potentially degrade in case of unintentional irradiation with UV light. Through this, many possible applications, in particular in the imaging field with detector arrays, can currently not be addressed or developed in an economical sensible way.

The third group of photodetectors in NIR is formed by devices that are based on the mechanism of internal photoemission. At the interface between a semiconductor and a metal, a potential barrier may be formed (Schottky junction or Schottky barrier), depending on the material pairing. Electrically, such an interface acts like a diode in which the current flow across the interface takes place only for one polarity. Such devices are called Schottky diodes. If electromagnetic radiation is incident on the metal layer at the interface, an electron (or hole, depending on the doping of the semiconductor) may be released from the metal and may transition into the adjacent semiconductor. These charge carriers can then again be measured as a photocurrent, cf. FIG. 7. FIG. 7 shows a schematic view of a Schottky junction between a metal and a semiconductor in the band model. As shown in FIG. 7, e.g., the semiconductor may be n-doped or may be strongly n-doped (n⁺). Through the contact area of the semiconductor with the metal, there is a shift of the valence band (E_{V}) and the conduction band (E_{C}) in the semiconductor in the area of the junction. The Fermi energy is indicated with E_{F}. Through an incident photon having the energy hv, an electron e from the metal may overcome the potential barrier E_{B} and may contribute to a photocurrent. The remaining hole is indicated with h.

The conventional technology knows planar designs of Schottky diodes. FIG. 5 schematically shows a simplified Schottky diode using planar technology. On a silicon substrate 1, a metal layer 2 is deposited, with the Schottky junction (or Schottky barrier) being created at the interface between the metal layer 2 and the substrate 1. In addition to the metal layer 2, a (ohmic) contact 3 for electrically contacting the substrate 1 is deposited. The contact is illustrated in a simplified way. It may consist of several layers and implementation areas in the substrate. For example, the substrate 1 may be n-doped. The metal layer 2 is provided with an electrical contacting 2a, the ohmic contact 3 with the contacting 3a. In case of a corresponding polarity, a current may flow across the contactings 2a and 3a through the diode.

When being irradiated with electromagnetic radiation, the diode of FIG. 5 may possibly be used as a photodiode, as schematically illustrated in FIG. 6. Illumination takes place from the rear side of the device through the substrate since the radiation on the front side of the metal 2 would only be reflected and would therefore not reach the interface between the metal 2 and the semiconductor substrate 1. Since the diode is operated in a wavelength range above the boundary wavelength of the semiconductor, the semiconductor substrate 1 is transparent for this wavelength range. After transmission of the substrate 1, the radiation 6 is incident on the metal layer 2. There, for example, an electron 4 may be conveyed out of the metal 2 across the Schottky barrier into the substrate 1. If a sufficient number of charge carriers is “generated” in this way, they may be measured as a photocurrent 7 across the contactings 2a and 3a.

The greatest disadvantage of the above-described use of planar Schottky diodes as photodiodes is the very low sensitivity. Releasing charge carriers out of the metal 2 takes place only in a very thin interface of the metal since the charge carriers otherwise lose their energy by dispersion processes in the metal before reaching the Schottky barrier. In addition, the probability for release that goes along with an energetic excitation of the charge carriers in the metal 2 is generally low. The largest part of the radiation is reflected by the planar metal layer 2 acting as a mirror and is therefore lost. Thus, simple planar Schottky diodes have not found use as photodiodes.

In science, some approaches for increasing the sensitivity for Schottky photodiodes have been examined. On the one hand, the planar metal layer 2 may be integrated into an optical resonator. To this end, in the simplest case, a dielectric mirror layer tuned to a wavelength is deposited on the rear side of the substrate 1. Together with the metal layer 2, this results in a resonator that reduces the reflection losses of the metal layer due to multi-reflection in the resonator. Different designs of this principle have been examined [1]. However, the moderate improvement of the sensitivity achieved in this approach is significantly limited by two significant disadvantages. The Q factor of the optical resonator strongly depends on the wavelength of the radiation. Through this, the wavelength range for which the sensitivity can be increased is too small for many applications. Furthermore, there is a strong dependency on the angle of incidence of the radiation in such a design. This is also disadvantageous for many applications.

In other words optimization methods that try to increase the efficiency of such device approaches by absorbing the incident radiation to a large part or even fully are known from science and practice. This may be realized by a structured surface within the detector [2, 4], the realization of layer stacks having optimized mirror properties [5, 6], or the use of plasmonic structures, with these also being used in combination with structured surfaces [7-9]. A special form of a plasmonic structure used for absorbing incident radiation is a so-called “plasmonic perfect absorber” [10]. In this case, plasmonically active structures are arranged in front of a continuous metallization such that there is an approximately full absorption of the incident radiation within the plasmonic structure for specific frequencies. This behavior is based on the excitation of nanostructures in their eigenfrequency. The prior art describes such structures only in the sense of the pure absorption of the incident radiation. Complete devices in connection with internal photoemission as a mechanism for generating a photocurrent are not described to date. The absorber structures known from the prior art convert the absorbed radiation into heat (energy conservation).

A further approach is the renunciation of the planar design with the goal of achieving light bundling by appropriate structures in silicon and increasing the optical radiation performance at the Schottky junction (and therefore the sensitivity). To this end, the prior art and science specifically describe pyramidal or V-trench structures in the silicon substrate [2], [3]. FIG. 8 schematically shows such a pyramidal structure 10 in a silicon substrate 1 in a side view. The pyramids (carrying out the structuring only in one direction results in V trenches or ridges) are manufactured using an anisotropic wet-chemical etching method, e.g. etching with TMAH. This results in very clean well-defined surface areas. The metal 11 for the Schottky junction is advantageously deposited only in the area of the pyramid tip. When being illuminated from the rear side, the radiation is reflected at the side faces of the pyramid and is guided towards the tip. What is now important is that the flank angles (or thread angles) of the pyramids are determined in a crystallographic way and can therefore not be selected freely. Round structures or such structures with a multiple base cross-section cannot be manufactured with this method due to the predefined crystal planes.

However, a precise observation shows that the light-collecting characteristic of the wet-chemically manufactured structures described in the literature only has a very limited effect on the increase of sensitivity. This situation is schematically illustrated in FIG. 9. This figure shows the cross-section of a pyramidal structure 10 and a section out of the silicon substrate 1 from which the structure was created by etching. The flank angle α 12 which the crystal facet forms with the normal 13 to the substrate front side is 35.3° for the wet-chemically etched structures, and, as described above, cannot be changed in terms of process technology. The tip of the structure is covered with a metal 15. The Schottky junction is formed between this metal 15 and the silicon pyramid 10. Thus, a photocurrent can only occur in the area of the tip. Depending on the precise location of entry of the radiation, there are different light paths. The simplified light beam model of the field of optics can be used for the analysis, even if there are diffraction effects in the area of the tip.

FIG. 9 exemplarily shows three different light beams. A first beam 16 enters almost perpendicular to the substrate surface, strikes the pyramid 10 approximately in the center and reaches the metallized tip 15 directly. A second beam 17 also enters almost perpendicularly, however, strikes the pyramid 10 at one of its facets and is reflected there for a first time. The reflected beam then also strikes the metallized tip 15. However, a full reflection of the beam 17 only takes place on the condition that it is a total reflection, since there is no longer any metallization at this location. The condition for a total reflection is determined by the jump of the refractive index at the facet interface and the angle of incidence of the light beam. If this angle becomes too small, only a part of the radiation will be reflected, another part will be refracted and will leave the pyramidal structure (and will be lost). In this way, in principle, by multi-reflection at the opposite facets, a beam or at least a part of the associated light output can reach the metallized tip 15. The situation becomes more unfavorable in the case in which the local angle of incidence becomes so small that the reflected part of the beam strikes the opposite facet under an angle that shows an exit direction of the reflected beam out of the pyramid 10 towards the substrate rear side. In this case, the radiation no longer strikes the metallized tip 15. The situation is illustrated with the beam 18 and the two partial beams 18a and 18b.

The smaller the flank angle α 12 (and therefore the steeper the pyramid), the more reflections are possible with a beam end point in the tip 15 and/or larger angles of incidence of the radiation to the substrate normal. For the structures described in the prior art, the flank angle is determined to be 35.3° by the process technology. This value leads to a very large limitation of the usable ratio of (projected) metallization width with respect to the base width and/or the usable angle spectrum of the incident electromagnetic radiation, since a large part of the radiation is lost due to unintentional retroreflection. Thus, the solutions described in the prior art are actually not suitable for creating a strong focusing effect and therefore an increase of sensitivity. For a meaningful use of the structures for focusing, the flank angle α 12 should or has to be significantly smaller.

Furthermore, so-called plasmonic effects may occur in metallic nanostructures. In this case, the electrons in the metal are excited by electromagnetic radiation to perform collective movements. In the metallized tip of the above-described pyramidal structures, such effects may occur and lead to a field superelevation. This may lead to an increase of the emission probability of charge carriers out of the metal into the semiconductor. This then leads to an improvement of the sensitivity of the device. However, this effect alone is not sufficient to make Schottky photodiodes sensitive enough for prevalent applications.

Thus, in the prior art, there are no solutions known that increase the sensitivity of Schottky photodiodes such that an application relevance is given.

Thus, it is the object of the present invention to provide a concept for a method and an apparatus for absorbing electromagnetic radiation that enable an improved compromise between sensitivity and effectiveness of radiation absorption as well as the manufacturing and integration effort.

A further underlying object of embodiments according to the present invention is the provision of a silicon photodiode that has a sufficient sensitivity in NIR for most applications and is therefore able to replace the detector material InGaAs (and also other materials).

### SUMMARY

An embodiment may have an apparatus for absorbing electromagnetic radiation, the apparatus comprising: a substrate with a main side, wherein the substrate is transparent for the electromagnetic radiation; and a beam guiding unit arranged on the main side of the substrate, wherein the beam guiding unit comprises a semiconductor material and wherein the semiconductor material is transparent for the electromagnetic radiation, and wherein the beam guiding unit comprises a first and a second portion, wherein the first portion is arranged facing the substrate and between the substrate and the second portion, and wherein a cross-sectional area of the beam guiding unit in parallel to the main side of the substrate decreases with an increasing distance to the main side more strongly in the second portion than in the first portion; and a metal material, wherein the metal material is arranged at the second portion of the beam guiding unit on a side of the second portion facing away from the substrate, and wherein the metal material provides together with the second portion a Schottky junction configured for absorbing the electromagnetic radiation.

Another embodiment may have a system for absorbing electromagnetic radiation, the system comprising a multitude of apparatuses according to the invention, wherein the apparatuses are arranged in a grid, and wherein the substrates of the multitude of apparatuses form a common substrate.

Another embodiment may have a method for absorbing electromagnetic radiation, the method comprising irradiating a rear side, opposite a main side of a substrate, of the substrate with the electromagnetic radiation, wherein the substrate is transparent for the electromagnetic radiation, so that the electromagnetic radiation enters into a beam guiding unit arranged on the main side of the substrate, and wherein the beam guiding unit comprises a semiconductor material, and wherein the semiconductor material is transparent for the electromagnetic radiation, and wherein the beam guiding unit comprises a first and a second portion, wherein the first portion is arranged facing the substrate and between the substrate and the second portion, and wherein a cross-sectional area of the beam guiding unit in parallel to the main side of the substrate decreases with an increasing distance to the main side more strongly in the second portion than in the first portion; and transmitting the electromagnetic radiation through the first and the second area of the beam guiding unit, or reflecting the electromagnetic radiation at a sidewall structure of the first and/or second portion of the beam guiding unit; and absorbing the electromagnetic radiation in a Schottky junction, wherein the Schottky junction is provided by a metal material together with the second portion, wherein the metal material is arranged at the second portion of the beam guiding unit on a side of the second portion facing away from the substrate.

Another embodiment may have a method for manufacturing an apparatus for absorbing electromagnetic radiation, the method comprising: providing a substrate with a main side, wherein the substrate is transparent for electromagnetic radiation; and arranging a beam guiding unit on the main side of the substrate, wherein the beam guiding unit comprises a semiconductor material, and wherein the semiconductor material is transparent for the electromagnetic radiation, and wherein the beam guiding unit comprises a first and a second portion, wherein the first portion is arranged facing the substrate and between the substrate and the portion, and wherein a cross-sectional area of the beam guiding unit in parallel to the main side of the substrate decreases with an increasing distance to the main side more strongly in the second portion than in the first portion; and arranging a metal material at the second portion of the beam guiding unit on a side of the second portion facing away from the substrate, wherein, together with the second portion, the metal material provides a Schottky junction configured for absorbing the electromagnetic radiation.

Embodiments according to the present invention include an apparatus for absorbing electromagnetic radiation, the apparatus including a substrate with a main side, wherein the substrate is transparent for the electromagnetic radiation; and a beam guiding unit (or means) arranged on the main side of the substrate, wherein the beam guiding unit comprises a semiconductor material, and wherein the semiconductor material is transparent for the electromagnetic radiation. The beam guiding unit includes a first and a second portion, wherein the first portion is arranged facing the substrate and between the substrate and the second portion. Furthermore, a cross-sectional area of the beam guiding unit in parallel to the main side of the substrate decreases with an increasing distance to the main side more strongly in the second portion than in the first portion.

In addition, the apparatus includes a metal material, wherein the metal material is arranged at the second portion of the beam guiding unit on a side, facing away from the substrate, of the second portion, and wherein, together with the second portion, the metal material provides a Schottky junction configured for absorbing electromagnetic radiation.

Embodiments according to the present invention are based on the core idea to guide, with the help of the beam guiding unit whose cross-sectional area decreases with an increasing distance to the main side of the substrate more strongly in the second portion facing away from the substrate more than in the first portion facing the substrate, incident electromagnetic radiation in such a way through the beam guiding unit that a large part of the radiation can be absorbed in the Schottky junction.

Accordingly, the beam guiding unit comprises a two-stage geometry. The inventors have found that this two-stage geometry is able to lead to an improved supply of incident electromagnetic radiation into the Schottky junction of the apparatus. However, it is to be noted that the beam guiding unit may also comprise a geometry that has more than two stages.

Thus, for example, the first portion of the beam guiding unit may therefore comprise a geometry that tapers only slightly with respect to a distance to the main side of the substrate. In other words, the first portion of the beam guiding unit may have sidewall structures that are steep (with respect to the main side of the substrate).

Thus, for example, the second portion of the beam guiding unit may comprise a geometry that tapers strongly with respect to a distance to the main side of the substrate. In other words, the second portion of the beam guiding unit may have sidewall structures that are flat (with respect to the main side of the substrate).

Through the inventive two-stage geometry of the beam guiding unit, large angles of incidence of the radiation with respect to the substrate normal are possible due to the less tapered geometry of the first portion, as already motivated above, so that a large part of the incident radiation can be forwarded to the metal material and therefore to the Schottky junction between the metal material and the second portion so as to be absorbed. That is, only a small part of the incident radiation may have angles of incidence that are unfavorable to such an extent that they cannot reach the Schottky junction. Through this, even small amounts of radiation can be detected.

However, the inventors have found that the disadvantages of a steep geometry of a beam guiding unit, e.g., that is an unfavorable ratio of a height (perpendicular to the main side of the substrate) to a base area (in parallel to the main side of the substrate) of the beam guiding unit, may be circumvented or reduced by dividing the geometry of the beam guiding unit.

Due to the second, e.g. flatter, portion, a vertical height (perpendicular to the substrate main side) of the beam guiding structure may be kept low, which simplifies manufacturing of an inventive apparatus. Through this, the advantages of a steep base, e.g., that is of the first portion, of the beam guiding unit may be connected with cost-efficient and widely used semiconductor manufacturing methods. For example, this may achieve a good ratio of the height to the base area so that a majority of the radiation incident in the base area may be guided up the metallization.

With respect to the two-stage geometry, it is to be noted that the feature of the cross-sectional area of the beam guiding unit in parallel to the main side of the substrate decreasing with an increasing distance to the main side more strongly in a second portion than in a first portion may also be understood such that the cross-sectional area of the beam guiding unit in parallel to the main side of the substrate decreases with an increasing distance to the main side more strongly in the second portion than in the first portion at the junction between the first and the second portion.

Accordingly, a cross-sectional area of the second portion (and therefore not necessarily the cross-sectional area at any given location of the second portion) decreases according to embodiments at least at one location more strongly than in the first portion. Thus, there is at least one spot in the second portion, e.g. advantageously at the transition from the first to the second portion, where the change of cross-section (with respect to the orthogonal distance to the substrate surface) is stronger in comparison to the first portion.

In this case, the feature may also be understood such that a cross-section in the second area decreases more strongly than in the first area, i.e. a geometry of the beam guiding unit tapers from the first to the second area, e.g. with an abrupt transition, e.g. with an unsteady transition (e.g. with respect to a function describing an external shape of the beam guiding unit in a lateral cross-section (e.g. in an idealized way)).

For example, that means that embodiments may comprise geometries where changes of cross-sectional areas in the first portion are stronger at a certain location (with respect to a vertical distance to the substrate surface) than at a certain location in the second portion.

Thus, a relative cross-sectional change may be greater or stronger in the second portion than in the first portion. Compared to an absolute change of the cross-sectional area, e.g. measured in μm² or nm² depending on the step size of the vertical distance to the substrate surface, a relative change may be expressed as a percentage decrease per step size of the vertical distance to the substrate surface. While, in case of a constant incline within the first portion and a constant incline, different to the first portion, within the second portion, the absolute change of the cross-sectional area changes with an increasing distance, possibly decreases by square, a relative change may remain constant.

On the basis of the same “starting cross-section”, which may understood as any virtual starting value, e.g. at the transition between the first and the second portion, e.g., the cross-sectional area decreases more strongly in the second portion than in the first portion.

Thus, a better compromise between sensitivity and effectiveness of the absorption of radiation as well as manufacturing and integration efforts may be achieved.

According to further embodiments of the present invention, the first portion of the beam guiding unit comprises a first sidewall structure that is inclined, starting from the substrate, with a first inclination angle with respect to a surface normal of the main side so that the first portion tapers starting from the substrate so as to focus the electromagnetic radiation received on the substrate. In other words, the beam guiding unit may comprise an inclined sidewall so as to guide and/or focus incident electromagnetic radiation towards the Schottky junction. This may improve the absorption efficiency of the apparatus.

According to further embodiments of the present invention, the second portion comprises a second sidewall structure that is inclined, starting from the first portion, with a second inclination angle with respect to a surface normal of the main side, wherein the second inclination angle is larger than the first inclination angle, so that the second portion tapers starting from the first portion. Simply put, sidewalls of the first and second portions may have different flank angles. Through this, a majority of the electromagnetic radiation incident in the beam guiding unit may be forwarded to the Schottky junction by the apparatus, e.g. by means of a small first inclination angle of the first sidewall structure of the first portion, and the beam guiding unit may at the same time have an advantageous height-to-base area ratio, which is why the apparatus may be manufactured with little effort.

According to further embodiments of the present invention, the second portion with the second sidewall structure is configured to focus the electromagnetic radiation received from the substrate and/or to facilitate absorption of the electromagnetic radiation in the Schottky junction by means of plasmonic effects. In turn, the second portion may comprise an inclination angle that is dimensioned such that electromagnetic radiation is deflected at an interface of the second portion to the surrounding area towards the metallization. The apparatus may therefore have a good absorption effectiveness.

According to further embodiments of the present invention, the first inclination angle is at least 1° and at most 25°, or the first inclination angle is less than 10°. Alternatively or additionally, the second inclination angle may be at least 10° and at most 90°. The inventors have recognized that an efficient beam deflection towards the Schottky junction can be enabled within these angular ranges.

According to further embodiments of the present invention, the first inclination angle is an angle between a tangent of the first sidewall structure and the surface normal at the transition between the first and the second portion of the beam guiding unit.

Alternatively or additionally, the second inclination angle is an angle between a tangent of the second sidewall structure and the surface normal at the transition between the first and the second portion of the beam guiding unit.

Alternatively, the first inclination angle is an angle between a secant of the first sidewall structure and the surface normal, wherein the secant is determined by two points that overlap vertically, with respect to the main side of substrate, on the first sidewall structure, wherein a first one of the two points is located in a sectional line between the first sidewall structure and the main side of the substrate, and wherein a second of the two points is located in a sectional line between the first and the second portion of the beam guiding unit. Alternatively or additionally, the second inclination angle is an angle between a secant of the second sidewall structure and the surface normal, wherein the secant is determined by two points that overlap vertically, with respect to the main side of the substrate, on the second sidewall structure, wherein a first of the two points is located in a sectional line between the first and the second portion of the beam guiding unit, and wherein a second of the two points forms a point of the second portion with the largest vertical distance to the main side of the substrate.

Simply put, the inclination angles may be flank angles at a transition between the first/second portion, or averaged flank angles.

According to further embodiments of the present invention, the Schottky junction is adapted to a wavelength range, and a width of an interface between the first and second portion of the beam guiding unit projected onto the base area of the beam guiding unit is at least 0.2 times a wavelength of the wavelength range and at most 15 times a wavelength of the wavelength range, wherein the base area of the beam guiding unit is a sectional area of the beam guiding unit with the substrate. Through this, an advantageous geometry of the beam guiding unit may be set for specific applications and specific wavelength ranges, wherein said geometry may have a height that is advantageous with respect to manufacturing while at the same time having good absorption properties.

According to further embodiments of the present invention, the first and/or the second sidewall structure is configured to be straight or curved. Embodiments are not limited to a specific shape of the sidewall structures, e.g., so that it is possible to manufacture apparatuses in large numbers with fast etching processes, so that requirements with respect to the specific design of the sidewall structures do not have to be satisfied.

According to further embodiments of the present invention, the second portion of the beam guiding unit has a tip or a flattened tip on a side facing away from the substrate, wherein the metal material is arranged only in the area of this tip or flattened tip. Embodiments according to the present invention are not limited to a single design of the end, facing away from the substrate, of the second portion of the beam guiding unit. For example, a flattened tip that is advantageous with respect to manufacturing technology may be generated, wherein said flattened tip may facilitate low-cost manufacturing, wherein the apparatus may still comprise good absorption properties due to the beam guidance.

According to further embodiments of the present invention, the Schottky junction is adapted with respect to a wavelength range, and the second portion comprises a flattened tip, wherein a flattened area of the tip comprises a width, in parallel to the main side of the substrate, that is smaller than a smallest wavelength of the wavelength range, or that corresponds to the smallest wavelength of the wavelength range. For example, for practical applications, or in other words in practice, the flattened area or the width of the tip may be typically configured so as to not be much smaller than the smallest wavelength in the semiconductor (e.g. not much smaller than the smallest wavelength of the wavelength range). Thus, depending on the wavelengths to be absorbed, good absorption properties may be set for specific applications.

According to further embodiments of the present invention, the tip or the flattened tip of the beam guiding unit is configured to cause and/or amplify plasmonic effects in the metal material deposited in the area of the tip. The absorption of the electromagnetic radiation may be facilitated by plasmonic effects.

According to further embodiments of the present invention, the semiconductor substrate includes a layer stack and/or the semiconductor material of the beam guiding unit includes silicon, germanium and/or a metal material compound including silicon and/or germanium. According to embodiments of the present invention, silicone technology, which is cost-efficient and widely available, may be used to manufacture inventive apparatuses. In this case, due to the absorption efficiency improved according to invention, silicon may also be used in wavelength ranges (e.g. NIR) for which silicone has insufficient radiation absorption in conventional approaches.

According to further embodiments of the present invention, the metal material includes a layer stack and/or the metal material includes a metal, a silicide, and/or a metal nitride.

According to further embodiments of the present invention, the metal material includes at least one of aluminum, copper, nickel, gold, titanium, nickel silicide, cobalt silicide, titanium silicide, and/or titanium nitride.

Embodiments according to the present invention enable the use of a multitude of metal materials, e.g., so that an advantageous material combination of the beam guiding unit and the metal material, e.g. a metallization, may be used depending on the radiation to be detected.

According to further embodiments of the present invention, the semiconductor material of the beam guiding unit comprises a doping, wherein a doping degree of the doping towards the Schottky junction is constant, stepped, or gradually variable. Depending on the manufacturing method and specific field of application, an advantageous doping profile may be set.

According to further embodiments of the present invention, the beam guiding unit comprises an at least partially round, elliptical, or polygonal base area, wherein the base area of the beam guiding unit forms the sectional area of the beam guiding unit with the substrate. For example, the base area may have a form of a flattened semi-circle. Depending on the manufacturing method and/or a further integration with a multitude of further apparatuses for absorbing radiation, a multitude of basic shapes of the beam guiding unit may be used so that an available substrate surface may be utilized efficiently, for example.

According to further embodiments of the present invention, the beam guiding unit comprises a height, vertical to the main side of the substrate, of at least 0.5 μm and at most 25 μm. The inventors have found that, by dividing the geometry of the beam guiding unit, beam guiding units with an efficiently manufacturable height profile with good absorption properties may be employed.

According to further embodiments of the present invention, the apparatus is configured for absorbing electromagnetic radiation with wavelengths in the range of at least 1000 nm and at most 3000 nm, or of at least 1000 nm and at most 1700 nm. For example, the apparatus may be configured for absorbing radiation in a wavelength range that may be used for telecommunication applications. Due to the improved beam guiding properties and the improved absorption, material combinations may also be used for wavelength ranges for which they previously did not have sufficiently good absorption properties, so that inventive apparatuses may be manufactured with little time and integration effort, e.g. due to the use of established materials such as silicon.

According to further embodiments of the present invention, the apparatus comprises a first and a second electrical contacting, wherein the first contacting is connected in an electrically conductive way to the metal material; and wherein the second contacting is connected in an electrically conductive way to the semiconductor material. In this case, the first and second contactings are configured to provide a photocurrent on the basis of an internal photoemission through electromagnetic radiation absorbed at the Schottky junction. By means of the contacting, the photocurrent may be provided to other circuit parts or an evaluation apparatus, for example.

According to further embodiments of the present invention, the first and second contacting are arranged at the opposite side of the apparatus. Alternatively, the first and second contactings are arranged on the same side of the apparatus. Simply put, embodiments according to the present invention may comprise a front side contacting or a rear side contacting. Depending on a further integration with further elements, an advantageous design may be selected so that a good compromise may be achieved between the efforts for manufacturing and integration.

Further embodiments of the present invention include a system for absorbing electromagnetic radiation, the system including a multitude of the inventive apparatuses, wherein the apparatuses are arranged in a grid, and wherein the substrates of the multitude of apparatuses form a common substrate. According to the invention, detectors may therefore be built out of a multitude of previously described apparatuses that are able to absorb and detect very little amounts of incident radiation. Through an individual evaluation, e.g., there may be a localization of radiation in the Schottky junction of the individual apparatuses. For example, the system may include structures, i.e. the apparatuses or beam guiding units, as a multipixel array so as to function as an image sensor.

According to further embodiments of the present invention, the system is an image sensor. Thus, silicon-based image sensors may be provided with low cost and good availability and efficiency.

According to further embodiments of the present invention, the multitude of apparatuses is arranged in a rectangular, square, or hexagonal grid. Thus, any “free” substrate areas may be occupied with inventive radiation sensors so that the available chip area can be utilized efficiently.

According to further embodiments of the present invention, the metal materials of the multitude of apparatuses comprise a first common contacting and/or the common substrate comprises a second common contacting. For example, by being arranged in a grid, contactings may be combined, thereby decreasing the effort for integration.

Further embodiments including methods according to the present invention will be described in the following. Inventive methods are based on the same or similar considerations and ideas as inventive apparatuses so that inventive methods may have corresponding features, functionalities, and advantages of apparatuses, individually or in combination. Vice versa, inventive apparatuses may also have corresponding features, functionalities, and advantages of methods, individually or in combination.

Further embodiments according to the present invention include a method for absorbing electromagnetic radiation, the method including irradiating a rear side, opposite a main side of a substrate, of the substrate with the electromagnetic radiation, wherein the substrate is transparent for the electromagnetic radiation, so that the electromagnetic radiation enters into a beam guiding unit arranged on the main side of the substrate, and wherein the beam guiding unit comprises a semiconductor material, wherein the semiconductor material is transparent for the electromagnetic radiation. Furthermore, the beam guiding unit includes a first and a second portion, wherein the first portion is arranged facing the substrate and between the substrate and the second portion, and wherein a cross-sectional area of the beam guiding unit in parallel to the main side of the substrate tapers with an increasing distance to the main side more strongly in a second portion than in a first portion. Furthermore, the method includes transmitting the electromagnetic radiation through the first and the second area of the beam guiding unit, or reflecting the electromagnetic radiation at a sidewall of the first and/or second portion of the beam guiding unit; and absorbing the electromagnetic radiation in a Schottky junction, wherein the Schottky junction is provided by a metal material together with the second portion, and wherein the metal material is arranged at a second portion of the beam guiding unit on a side of the second portion facing away from the substrate.

Further embodiments according to the present invention include a method for manufacturing and an apparatus for absorbing electromagnetic radiation, the method including providing a substrate with a main side, wherein the substrate is transparent for electromagnetic radiation, and arranging a beam guiding unit on the main side of the substrate, wherein the beam guiding unit comprises a semiconductor material. In this case, the semiconductor material is transparent for the electromagnetic radiation, and the beam guiding unit includes a first and a second portion, wherein the first portion is arranged facing the substrate and between the substrate and the second portion, and wherein a cross-sectional area of the beam guiding unit in parallel to the main side of the substrate decreases with an increasing distance to the main side more strongly in the second portion than in the first portion. Furthermore, the method includes arranging a metal material at the second portion of the beam guiding unit on a side of the second portion facing away from the substrate, wherein, together with the second portion, the metal material provides a Schottky junction configured for absorbing the electromagnetic radiation.

According to further embodiments of the present invention, arranging the beam guiding unit includes a dry-chemical and/or wet-chemical etching method. Inventive manufacturing methods may include dry etching methods, e.g. for manufacturing straight sidewall structures. Furthermore, depending on the application, wet-chemical etching methods may also be used, e.g. for generating curved sidewall structures. In general, embodiments of the present invention are not limited to a specific type of etching method, enabling further degrees of freedom with respect to an integration into existing manufacturing processes.

According to further embodiments of the present invention, arranging the beam guiding unit further includes arranging a semiconductor material on the substrate; and etching the semiconductor material by means a dry-chemical etching method in two directly subsequent process steps by using at least two parametrizations. In this case, etching the semiconductor material includes etching the semiconductor material in a first process step with the dry-chemical etching method with a first parametrization for generating the first portion of the beam guiding unit, and etching the semiconductor material in a directly subsequent second process step with the dry-chemical etching method with a second parametrization for generating the second portion of the beam guiding unit. In this case, the first and second parametrizations of the dry-chemical etching method are selected such that a cross-sectional area of the beam guiding unit in parallel to the main side decreases with an increasing distance to the main side more strongly in the second portion than in the first portion.

Thus, the beam guiding unit may be manufactured in two directly subsequent etching steps without removal from an etching apparatus, thereby saving time and not requiring placement into further apparatuses for etching so that the beam guiding unit may be generated with good precision.

According to further embodiments of the present invention, the method further includes providing a carrier layer; and arranging an insulator layer on the carrier layer; and arranging the semiconductor material on the insulator layer; and at least partially removing the carrier layer after arranging the beam guiding unit. For example, the carrier layer may also include a semiconductor material and may provide the apparatus with mechanical stability during processing and may at least be partially removed again after processing. Accordingly, embodiments of the present invention may comprise a silicon-on-insulator (SOI) substrate.

According to further embodiments of the present invention, the method further includes arranging a plurality of beam guiding units on the main side of the substrate and arranging the metal material at the second portions of the beam guiding units on a side of the second portion facing away from the substrate, wherein arranging the plurality of beam guiding units includes partially removing the semiconductor material in an area between at least two neighboring beam guiding units and arranging a common contacting of the at least two neighboring beam guiding units in the area of the partially removed semiconductor material.

In other words, neighboring structures may share common electrical contacts. A common electrical contact may be configured as a metallic ridge, for example. With a common contacting, on the one hand, the contacting effort may be decreased, and on the other hand, small photocurrents of a plurality of Schottky junctions may be combined so that even little incident radiation on the respective beam guiding units may be detected.

### BRIEF DESCRIPTION OF THE DRAWINGS

Embodiments of the present invention will be detailed subsequently referring to the appended drawings, in which:

FIG. 1 shows a schematic side view of an apparatus for absorbing electromagnetic radiation according to an embodiment of the present invention;

FIG. 2 shows a schematic side view of an apparatus for absorbing electromagnetic radiation with a flattened tip and a second portion of the beam guiding unit with a curved sidewall structure according to embodiments of the present invention;

FIG. 3 shows a schematic side view of an apparatus for absorbing electromagnetic radiation with a flattened tip and a first and a second portion of the beam guiding unit with respectively curved sidewall structures according to embodiments of the present invention;

FIG. 4a shows a schematic side view of an apparatus for absorbing electromagnetic radiation with a front side contacting according to embodiments of the present invention;

FIG. 4b shows a schematic side view of an apparatus for absorbing electromagnetic radiation with a rear side contacting according to embodiments of the present invention;

FIG. 5 shows a schematic side view of a simplified Schottky diode using planar technology;

FIG. 6 shows a schematic side view of the Schottky diode of FIG. 5 when being irradiated;

FIG. 7 shows a schematic view of a Schottky junction between a metal and a semiconductor in the band model;

FIG. 8 shows a schematic side view of a pyramidal structure in a silicon substrate;

FIG. 9 shows a schematic cross-section of a pyramidal structure and a section out of a silicon substrate from which the structure was created by etching, with a schematic illustration of an example of a beam path;

FIG. 10 shows a schematic illustration of a pyramidal structure with a schematic illustration of an example of a beam path, created through successive reflections, in the pyramidal structure being unfolded;

FIG. 11 shows a schematic side view of a system for absorbing electromagnetic radiation according to embodiments of the present invention;

FIG. 12 shows a schematic side view of a beam guiding unit according to embodiments of the present invention;

FIG. 13 shows a schematic side view of a conical photodiode according to embodiments of the present invention, with a schematic illustration of an example of a beam path in the conical photodiode;

FIG. 14 shows schematic top views of beam guiding units according to the present invention;

FIG. 15 shows schematic side views of two beam guiding units according to embodiments of the present invention;

FIG. 16 shows a schematic top view of a system for absorbing electromagnetic radiation having a multitude of apparatuses with a square base area of the beam guiding units, arranged in a square grid;

FIG. 17 shows a schematic top view of a system for absorbing electromagnetic radiation with a multitude of apparatuses with a round base area of the beam guiding units, arranged in a hexagonal grid;

FIG. 18 shows a schematic side view of a SOI substrate according to embodiments of the present invention;

FIG. 19 shows a schematic side view of a multitude of apparatuses for absorbing electromagnetic radiation, being arranged on a common substrate, according to embodiments of the present invention;

FIG. 20 shows a schematic side view of a multitude of apparatuses for absorbing electromagnetic radiation, being arranged on a common substrate, with a carrier layer being removed, according to embodiments of the present invention;

FIG. 21 shows a method for absorbing electromagnetic radiation according to an embodiment of the present invention; and

FIG. 22 shows a method for manufacturing an apparatus for absorbing electromagnetic radiation according to embodiments of the present invention.

### DETAILED DESCRIPTION OF THE INVENTION

Before embodiments of the present invention are subsequently described in detail on the basis of the drawings, it is to be noted that identical and functionally identical elements, objects, and/or structures or elements, objects, and/or structures having the same effect are provided with the same or similar reference numerals in the different drawings so that the description of these elements illustrated in different embodiments is interchangeable or can be applied to one another.

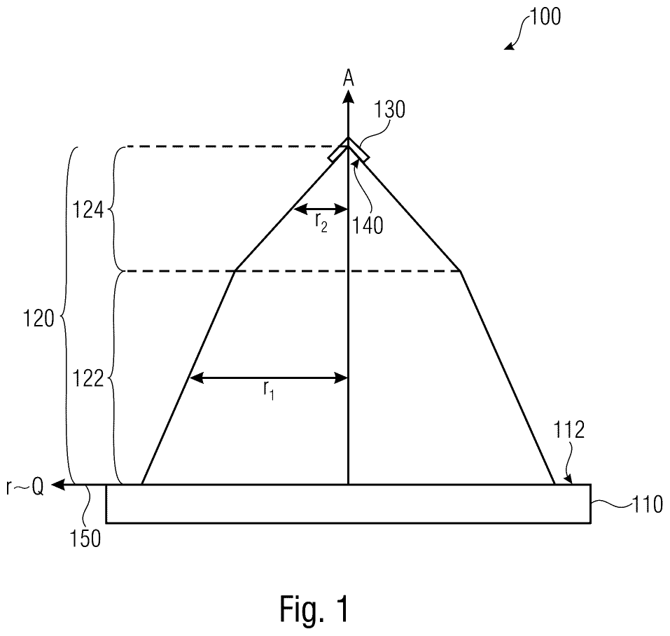

FIG. 1 shows a schematic side view of an apparatus for absorbing electromagnetic radiation according to embodiments of the present invention. FIG. 1 shows the apparatus 100 including a substrate 110 with a main side 112. A beam guiding unit (or means) 120 is arranged on the main side 112 of the substrate 110. The beam guide unit comprises a first portion 122 and a second portion 124, wherein the first portion is arranged on the main side 112 of the substrate 110, wherein the second portion 124 is arranged on a side of the first portion 122 facing away from the substrate 110. The cross-sectional area (in parallel to the substrate main side 112) of the second portion 124 of the beam guiding unit 120 decreases with an increasing distance to the main side 112 more strongly than the cross-sectional area (in parallel to the substrate main side 112) of the first portion 122 of the beam guiding unit 120 with an increasing distance to the main side 112.

To highlight the cross-sectional change, the coordinate system 150 is indicated in FIG. 1 for an optional implementation as a beam guiding unit with a round cross-sectional area. As an example for a round inventive cross-sectional geometry, a radius r₁ (and therefore the associated cross-sectional area Q) of the first portion 122 of the beam guiding unit 120 decreases with an increasing distance A to the main side 112 of the substrate 110 less than a radius r₂ (and therefore the associated cross-sectional area Q) of the second portion 122 of the beam guiding unit 120 with an increasing distance A to the main side 112 of the substrate 110. Thus, a gradient dᵣ₁/dA would be smaller in size than a gradient dᵣ₂/dA, for example. Here, it is to be noted that the example of a round geometry and the consideration of radiuses are only used to illustrate the cross-sectional change. Inventive apparatuses may have a multitude of base shapes and geometries.

Furthermore, a metal material 130 is arranged at the second portion 124 of the beam guiding unit 120 on a side of the second portion 124 facing away from the substrate.

The substrate 110 is at least approximately or at least partially transparent for a wavelength range of electromagnetic radiation to be absorbed so that the radiation can be transmitted through the substrate to the beam guiding unit 120 in case of illumination of the side of the substrate 110 facing away from the substrate 112.

In turn, the beam guiding unit 120 comprises a semiconductor material that is also at least partially or at least approximately transparent for the electromagnetic radiation to be absorbed. Thus, the electromagnetic radiation transmitted through the substrate 110 may be transmitted into the beam guiding unit 120.

Due to the small change of the cross-sectional area of the first portion 122 of the beam guiding unit with respect to the distance A to the main side 112, the first portion 122 may have a steep sidewall structure with respect to the main side 112. Through this, the first portion 122 of the beam guiding unit 120 may have a focusing effect for incident radiation for a multitude of angles of incidence. In this case, the angles of incidence may be measured against the substrate normal, for example. Simply put, due to a steep rise of the outer surface of the beam guiding structure 120 with respect to the main side 112 of the substrate 110, a majority of the radiation transmitted into the beam guiding structure 120 can be transmitted towards the metal material 130, so that the part of the incident radiation comprising, with respect to an interface between the beam guiding structure 120 and the surrounding area, a local angle of incidence that would lead to a diffraction out of the beam guiding structure 120 can be kept to a minimum.

As described above, the design of the second portion 124 of the beam guiding structure 120 enables, despite the use of the advantage of the “steep” first portion 122, a limitation of the height of the beam guiding unit, or in other words, the advantages of good beam guiding properties may be synergistically combined with the advantages of a low height of the beam guiding unit (e.g. the height in the A direction).

Starting from the first portion, the incident electromagnetic radiation may be guided directly to the metal material 130, or via reflection at an interface of the second portion 124 (or also via further reflections in the first portion).

In this case, the metal material 130 is configured to form, together with the second portion 124, e.g., i.e. with the semiconductor material of the beam guiding unit 120 of the second portion 124, a Schottky junction 140 so that the electromagnetic radiation guided to the metal material and therefore to the Schottky junction 140 may be absorbed.

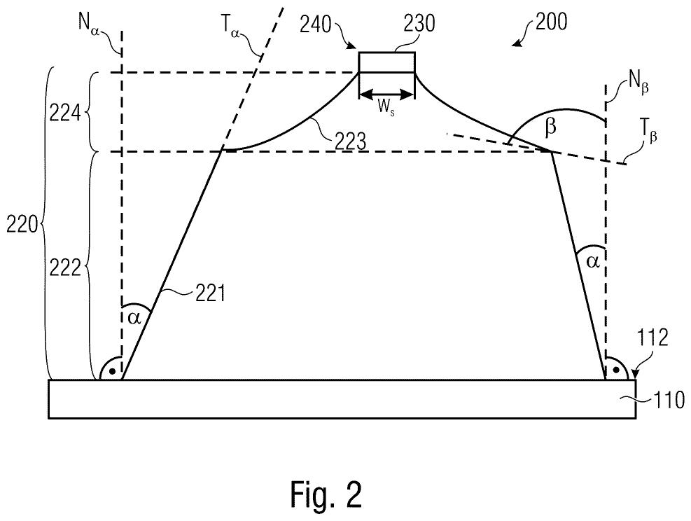

FIG. 2 shows a schematic side view of an apparatus for absorbing electromagnetic radiation with a flattened tip and a second portion of the beam guiding unit with a curved sidewall structure according to embodiments of the present invention. The apparatus 200 includes a substrate 110 with a main side 112 as well as a beam guiding unit 220. The first portion 222 of the beam guiding unit 220 comprises a sidewall structure 221, the second portion 224 of the beam guiding unit 220 comprises a sidewall structure 223.

As optionally shown in FIG. 2, the second portion 224 of the beam guiding unit 220 may comprise a flattened tip 240 on a side facing away from the substrate. As a further optional feature, the metal material 230 is arranged only in the area of the tip. Here, it is to be noted that the second portion may also have a non-flattened tip, as exemplarily shown in FIG. 1, and that the metal material may accordingly be arranged in an area around the tip.

As previously explained, the metal material is configured to form, together with the semiconductor material of the second portion 224, a Schottky junction for absorbing electronic magnetic radiation. Here, the Schottky junction may be adapted to a wavelength range or, in other words, by selecting an appropriate material, it may be configured to efficiently absorb radiation in a certain wavelength range. In this case, a width W_{S} of a flattened area of the tip 240 may have a width, in parallel to the main side 112, that is smaller than a smallest wavelength of the wavelength range, or that is in the order of magnitude of a wavelength in the corresponding wavelength range. Thus, the absorption of the electromagnetic radiation may be facilitated, e.g. due to a reduction of the reflection components of the electromagnetic radiation.

In general, embodiments according to the present invention may be configured for absorbing electronic magnetic radiation with wavelengths in the range of at least 1000 nm and at most 3000 nm or of at least 1000 nm and at most 1700 nm.

Optionally, the semiconductor material of the beam guiding unit 220 may comprise a doping, and a doping degree of the doping towards the Schottky junction may be configured to be constant, stepped, or gradually variable.

According to embodiments, the tip 240 (or also a non-flattened tip) may be configured to cause and/or amplify plasmonic effects in the metal material 230 deposited in the area of the tip. With this, in turn, absorption of the electromagnetic radiation may be facilitated.

As optionally shown in FIG. 2, the sidewall structure 221 of the first portion may be inclined with a first inclination angle α with respect to a surface normal Na of the main side so that the cross-sectional area of the first portion 222 tapers with an increasing vertical distance to the main side 112 of the substrate. Due to the tapered geometry, starting from the substrate, of the first portion, radiation transmitted into the first portion may be focused, e.g. towards the metal material 230 arranged at the second portion 224 of the beam guiding unit.

As a further optional feature, the sidewall structure 223 of the second portion 224 may also be inclined with respect to a surface normal NB of the main side. The associated inclination angle is B. According to embodiments, the second inclination angle β may be larger than the first inclination angle α so that the second portion 224 tapers starting from the first portion 222, so that a stronger decrease of the cross-sectional area of the second portion 224 may be set with an increasing vertical distance to the main side 112 compared to the decrease of the cross-sectional area of the first portion 222 with an increasing vertical distance to the main side 112.

Due to the geometry of the second portion 224 tapering more strongly (e.g. compared to the first portion 222), incident electromagnetic radiation may be focused by means the inclination of the sidewall structure, e.g. towards the metal material 230 so that a large or e.g. a majority of the incident radiation may be absorbed. Furthermore, due to the geometry of the second portion, a geometry, e.g. a lateral extension (with respect to the main side 112) of the metal material, may be configured such that plasmonic effects occur, said effects facilitating an absorption of incident radiation at the Schottky junction formed by the metal material 230 and the semiconductor material of the second portion 224.

As optionally shown in FIG. 2, a may be an angle between a tangent Ta of the first sidewall structure 221 and the surface normal Na at the transition between the first and the second portion of the beam guiding unit 220, for example.

Accordingly, as optionally shown in FIG. 2, the inclination angle β may be an angle between a tangent T_{β} of the second sidewall structure 223 and the surface normal NB at the transition between the first and the second portion of the beam guiding unit 220.

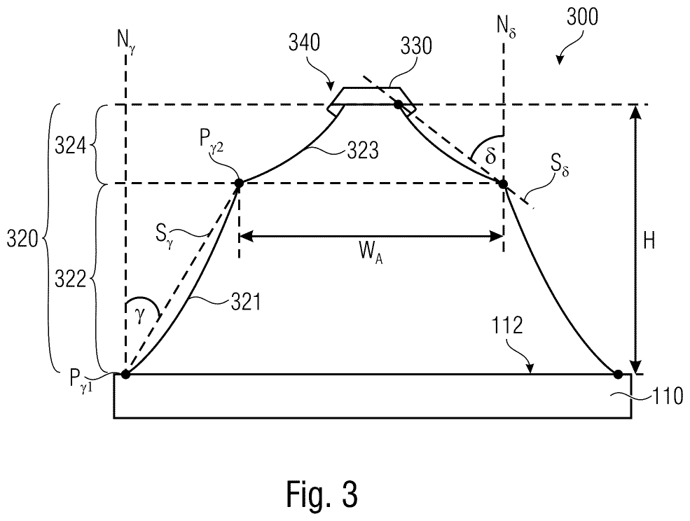

FIG. 3 shows a schematic side view of an apparatus for absorbing electromagnetic radiation with a flattened tip and a first and a second portion of the beam guiding unit each having curved sidewall structures according to the embodiments of the present invention. Compared to the apparatus 200, the first portion 322 and the second portion 324 of the beam guiding unit 320 of the apparatus 300 comprise curved sidewall structures 321, 323. In addition, the apparatus 300, corresponding to the apparatus 200, has a flattened tip 340. In contrast to the apparatus 200, the metal material 330, as shown in FIG. 3, may also be arranged outside of the direct flattened part of the tip, i.e. in an area around the flattened tip.

In general, any combinations of straight and curved sidewall structures may be used. In particular, a single portion of the beam guiding unit may have straight and curved sidewall structures both. In addition, it is also to be noted that embodiments according to the present invention are not limited to symmetrical beam guiding units. Thus, sidewall structures of portions of the beam guiding unit may each have different inclination angles. Accordingly, a tip of the second portion may also be arranged outside of an area around a lateral center of the second portion 324.

Furthermore, it is also to be noted that apparatuses according to the present invention may comprise a multitude of geometries of the beam guiding unit. Thus, the beam guiding unit 220 may comprise an at least partially round, elliptical, or polygonal base shape, wherein the base shape of the beam guiding unit forms the sectional area of the beam guiding unit with the substrate 110.

As shown in FIG. 3, the inclination angle of the first sidewall structure 322 may also be an inclination angle γ that is an angle between a secant Sₛ of the first sidewall structure 322 and the surface normal N_{γ}, wherein the secant is determined by two points overlapping vertically, with respect to the main side of the substrate, on the first sidewall structure, wherein a first one of the two points is located in a sectional line between the first sidewall structure 322 and the main side 112 of the substrate 110, and wherein a second of the two points is located in a sectional line between the first and the second portion of the beam guiding unit 320 (first point P_{γ1}, second point P_{γ2}).

Accordingly, the inclination angle of the second sidewall structure 322 may also be an inclination angle δ, which is an angle between a secant S_{δ} of the second sidewall structure 323 and the surface normal No, wherein the secant is determined by two points overlapping vertically, with respect to the main side 112 of the substrate, on the second sidewall structure 323, wherein a first one of the two points is located in a sectional line between the first and the second portion of the beam guiding unit and wherein a second of the two points forms a point of the second portion with the largest vertical distance to the main side of the substrate (first point P_{δ1}, second point P_{δ2}).

In general, the first inclination angle, e.g, i.e. angle α or angle γ, may be at least 1° and at most 25° or less than 10°. Alternatively or additionally, the second inclination angle, e.g., i.e. angle β or angle δ, may be at least 10° and at most 90°.

As a further optional feature, a width WA of an interface between the first and the second portion of the beam guiding unit 320 projected onto the base area of the beam guiding unit may be at least 0.2 times a wavelength of the wavelength range and at most 15 times a wavelength of the wavelength range, wherein the base area of the beam guiding unit 320 is a sectional area of the beam guiding unit with the substrate 110.

Furthermore, a height H, vertical to the main side of the substrate, of an inventive apparatus 300 may be at least 0.5 μm and at most 25 μm, for example.

With reference to FIGS. 1-3, the semiconductor substrate 110 may optionally include a layer stack. Furthermore, the semiconductor material of the beam guiding unit 120, 220, 320 may include at least one of silicon, germanium, and/or a material compound including silicon and/or germanium. In turn, the metal material 130, 230, 330 may also include a layer stack. Furthermore, the metal material 130, 230, 330 may include at least one of a metal, a silicide, and/or a metallic nitride. For example, the metal material 130, 230, 330 may comprise at least one of aluminum, copper, nickel, gold, titanium, nickel silicide, cobalt silicide, titanium silicide, and/or titanium nitride.

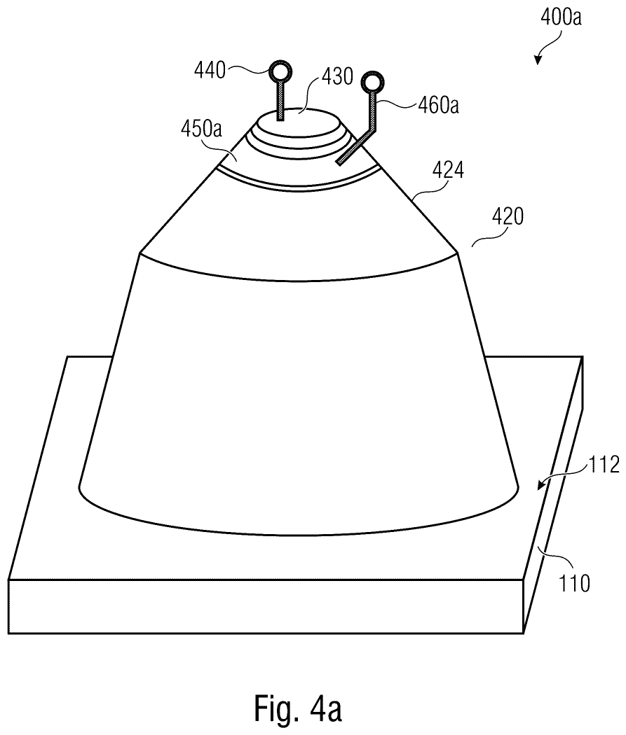

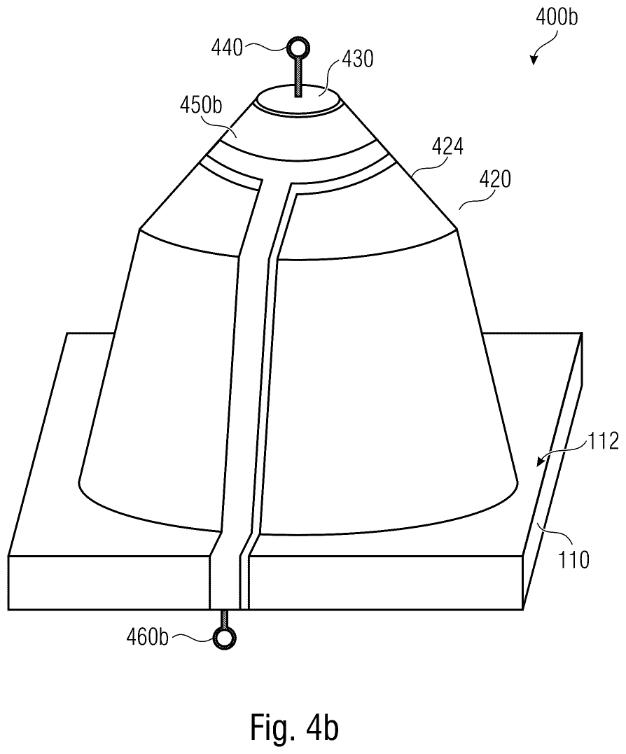

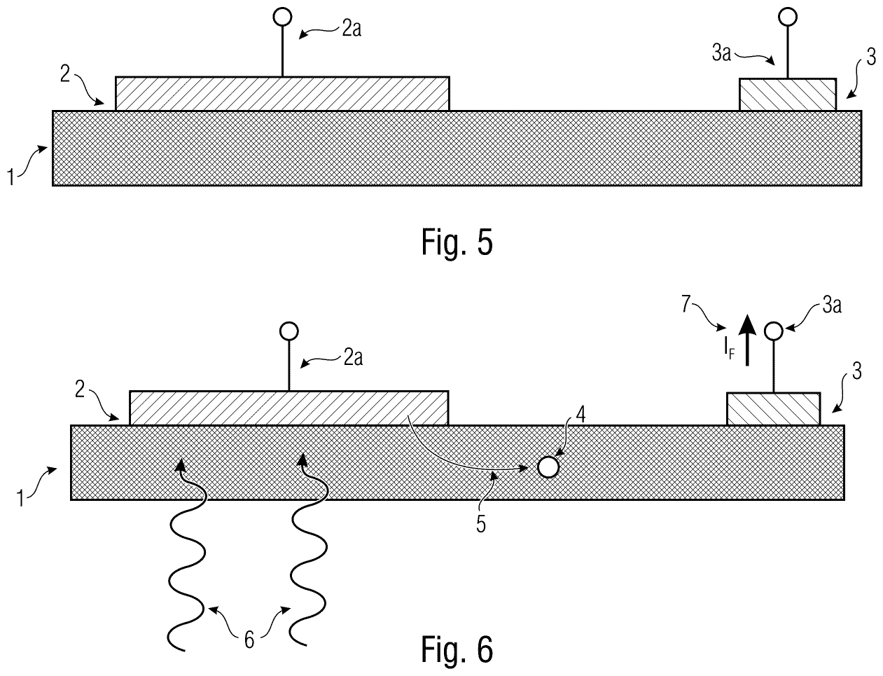

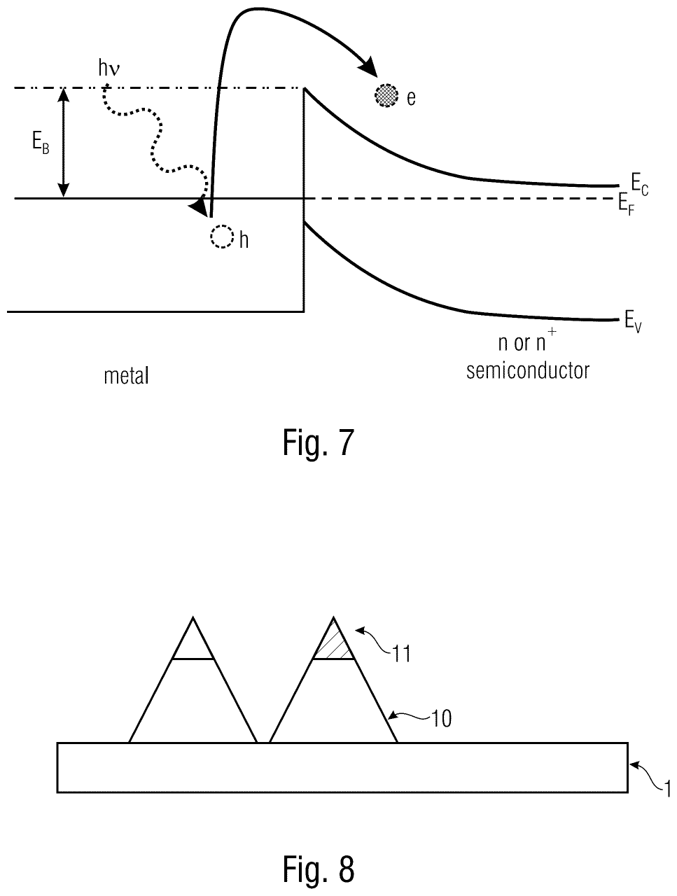

FIG. 4a shows a schematic side view of an apparatus for absorbing electromagnetic radiation with a front side contacting according to embodiments of the present invention, FIG. 4b shows a schematic side view of an apparatus for absorbing electromagnetic radiation with a rear side contacting according to embodiments of the present invention. The apparatuses 400a and 400b are shown in FIGS. 4a and 4b, respectively. Both apparatuses include a substrate 110 with a main side 112 and a beam guiding unit 420 that may be configured according to any of the preceding embodiments, for example. Both embodiments comprise as an optional feature a first contacting 440 connected in an electrically conductive way to the respective metal material 430.

The apparatus 400a comprises a contact material 450a, e.g., which may have good conductivity and is arranged at the semiconductor material of the second portion 424 of the beam guiding unit, e.g., in direct proximity to the metal material as shown in FIG. 4a.

According to the example of the apparatus 400a, the apparatus may comprise a second contacting 460a arranged on the contact material. The second contacting 460 is accordingly connected in an electrically conductive way to the semiconductor material of the beam guiding unit 420. Accordingly, the first and/or second contact material 450a, 450b may each be configured as an ohmic contact. For example, the contacting may also be provided via other conductive materials, such as doped semiconductor areas.

According to the example of the apparatus 400b, a contact material 450b may also be configured to provide an electrically conductive connection of the semiconductor area of the second portion in the direct proximity of the metal material 430 up to the side of the substrate 110 opposite the main side 112. Thus, a second contacting 460b may be arranged on the rear side of the substrate. The second contacting 460b is accordingly connected in an electrically conductive way to the semiconductor material of the beam guiding unit 420.

The first and second contactings may in both cases be configured to provide a photocurrent on the basis of an internal photoemission through electromagnetic radiation absorbed at the Schottky junction.

According to the example of the apparatus 400a, the first and second contactings may be located on a same side of the apparatus. Alternatively, the first and second contactings, as is the case in the apparatus 400b, may be located on opposite sides of the apparatus.

According to further embodiments, the contact 450a is arranged outside of the tip on the front side, and the contact 450b is arranged directly on the rear side (e.g. without a conductive trace on the front side, e.g. in direct substrate contact). For example, such an arrangement may be easier to realize than the apparatuses shown in FIGS. 4a and 4b with the ohmic contacts 450a and 450b.

Generally, embodiments according to the present invention may include front side or rear side contactings.

In the following, further embodiments are described, and some previously described embodiments are explained in other words. To this end, inventive ideas or ideas for solution of the invention according to embodiments are described in different words.

Embodiments according to the present invention are based on the finding that the pyramidal structures described in the prior art are in principle suitable to focus electromagnetic radiation in a small spatial area at the tip and to improve the sensitivity (e.g. the signal-noise ratio), however, the effect of this characteristic is insufficient for meaningful applications due to the flank angles being too large for technological reasons.

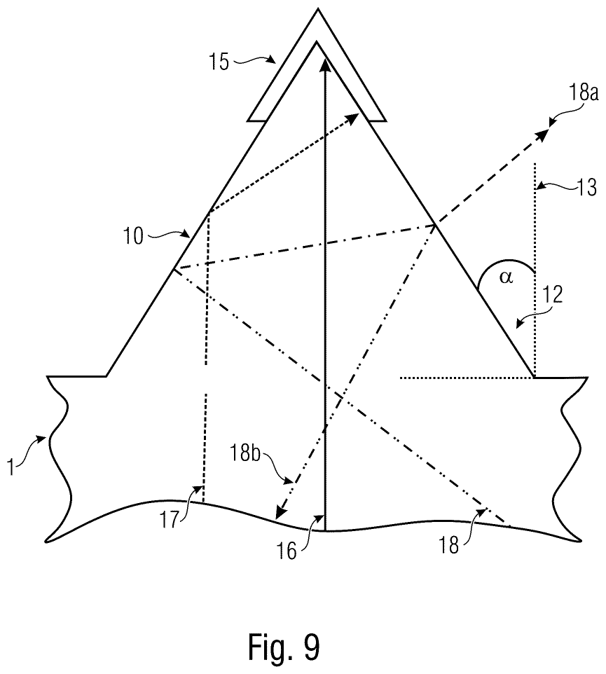

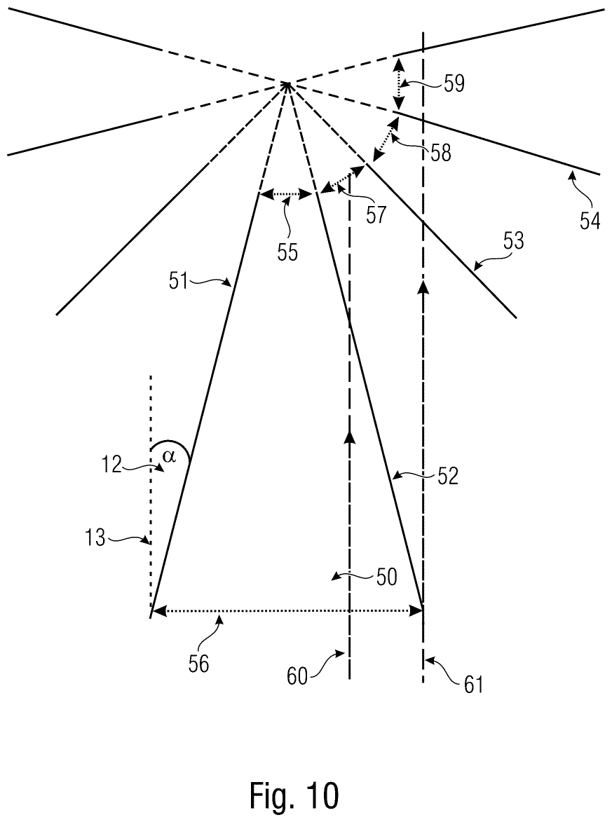

This situation is schematically shown in FIG. 10. The pyramidal structure 50 has a base 56 and a tip 55 representing the projection of the metallized area onto the base area. The flank angle α 12 is as defined in FIG. 9. Two facet edges 51 and 52 of the pyramid are illustrated. Reflection images 53 and 54 of the two facets 51 and 52 (mutual reflections) are also shown. The associated reflection images of the tip 55 are indicated with 57, 58 and 59. This illustration corresponds to an unfolding of the zig-zag course of light beams in the pyramid created by subsequently following reflections. Using the reflection images, light beams can be illustrated as straight lines. A first light beam 60 enters into the pyramid, crosses the facet 52 once, and strikes the reflection image 57 of the tip 55. In reality, this corresponds to a reflection at the facet 52. A second light beam 61 also enters into the pyramid, however, it crosses the facet 52 and the reflection images 53 and 54 in this order without striking one of the reflection images 57, 58 and 59. Rather, it crosses further reflection images of the facets 51 and 52 (no longer illustrated) without ever striking a reflection image of the tip 55. In reality, this means that the beam 61 leaves the pyramid after a series of reflections at the facets without ever having been detected, since it misses the tip 55.

The above analysis leads to the finding that, on the one hand, the metallization of the tip should have a meaningful minimum dimension (width/surface area projected onto the base area) depending on the base width, or even has to have it, since a majority of the radiation is otherwise able to leave the pyramid through reflection without being detected. On the other hand, by decreasing the flank angle α while maintaining the base and tip width, it can be achieved that a light beam is still able to strike the metallization after several reflections. Thus, the focusing characteristic of the structure may be improved significantly.

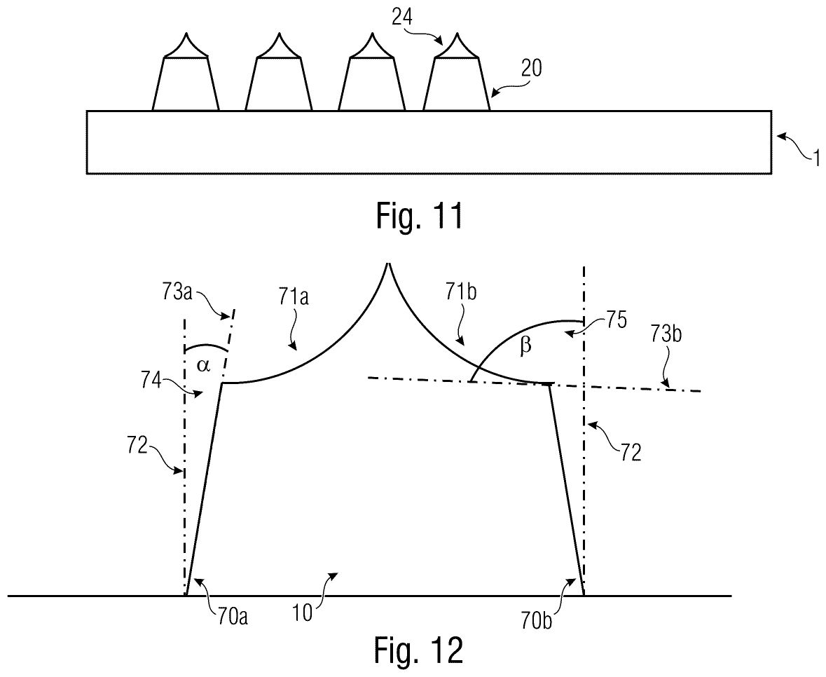

Accordingly, a first solution step may be a significant reduction of the flank angle, advantageously smaller than 10°, for example. However, while this makes the pyramid stepper, it may become significantly higher while maintaining its base area. This situation is not desirable, since the realization with standard methods of the semiconductor technology would be significantly more difficult with an increased structural height. An inventive solution of this problem is a division of the pyramidal structure in a lower area with a small flank angle and an upper area with a larger flank angle. The width of the upper area projected onto the base area of the structure may be advantageously in the order of magnitude of some wavelengths of the electromagnetic radiation in the semiconductor, for example. In other words, the Schottky junction may be adapted to a wavelength range, and a width of an interface between the first and the second portion of the beam guiding unit projected onto the base area of the beam guiding unit may be in an order of magnitude of some wavelengths of the wavelength range. A possible implementation variation is schematically shown as a side view in FIG. 11. FIG. 11 shows a schematic side view of a system for absorbing electromagnetic radiation according to embodiments of the present invention. The system includes a multitude of apparatuses, each comprising beam guiding units including a first portion 20 and a second portion 24. The beam guiding units are arranged on a common substrate 1 and may be arranged in a grid. In other words, the structures consist of the lower area 20 and the upper area 24 and may be manufactured from the substrate 1 using different dry-etching methods. In this case, the facet surfaces do not have to be required, as indicated for the upper area 24. For example, they may absolutely comprise a curvature. In addition to the height limitation, such a shape of the upper structure 24 may also have the large advantage of itself having a focusing effect, and in principle enabling the above-mentioned plasmonic effects due to the tapering ratio, for example. At this point, it is to be noted that a planar limitation of the beam guiding unit, here exemplarily configured as a pyramid (frustum of a pyramid) with a flat facet in parallel to the substrate surface, is easier with respect to the technological process, however, it may not be productive in this case. That is, a flat facet could predominantly act as a planar mirror and reflect back the majority of the radiation, for example. Since, as described above, the width (or the projected surface area) of the upper structure 24 should not be too small, or is not allowed to be too small, so as to still ensure or at least enable the focusing effect, a very small planar surface that would also allow plasmonic effects could be mostly ineffective here.

This novel approach of dividing these structures, which has not yet been described in the literature, is not limited to pyramids. For example, according to embodiments, by renouncing the anisotropic wet-chemical etching methods described in the literature in favor of dry-chemical processes, a much more diverse design can be enabled. In particular, different etching methods may be combined, e.g. by using a method in the lower area 20 that differs from that in the upper area 24 so that the surfaces are almost planar in the lower area 20 while having a curvature in the upper area 24. However, all meaningful usable structures still have the tapered shape in common. In other words, the cross-sectional area of the beam guiding unit in parallel to the main side of the substrate decreases with an increasing distance to the main side more strongly in the second portion than in the first portion. This is why they are described in the following using the term conical structures as examples for implementations of the beam guiding units, even though a cone has a round cross-sectional area in common parlance. In the sense of the invention, other cross-sectional shapes, such as polygons, circles, and ellipses are included, whose flank angle may change at least once.

According to embodiments of the invention, depositing the metal material, e.g. the metallization, may be advantageously carried out (however, not necessarily) in the area of the tip only. Since, charge carriers at a Schottky junction are also able to reach into the adjacent semiconductor via thermal excitation across the barrier, leading to an increased dark current, and to associated electrical noise, it may be very advantageous, for example, to keep the interface of the Schottky junction as small as possible. In connection with the focusing effect of the conical structure, or in other words, e.g., the first and/or second portion of the beam guiding unit with the inventive cross-sectional change guiding the radiation in the area of the metal material, e.g. of the metallization, a significant improvement of the signal-noise ratio may possibly follow.

A general description of the conical structures may be given via the shape of the edge curves (or border curves) in a section perpendicular to the substrate surface, for example. For example, the sections may in this case be advantageously placed such that they consider the possible symmetry of the conical structure. FIG. 12 exemplarily shows such a cross-section through, e.g., a round or square conical structure 10. FIG. 12 shows a schematic side view of a beam guiding unit according to embodiments of the present invention. In its lower area, the structure has as its edges the curve sections 70a and 70b. The curve sections 71a and 71b belong to the upper area. The different flank angles 74 and 75 are measured from the normal 72 to the substrate surface. Since the individual curve sections have a curvature, the tangents 73a and 73b to the curve sections are formed at the points at which they meet in order to give a meaningful definition of the flank angles 74 and 75. FIG. 12 shows that embodiments according to the present invention are able to distinguish themselves in this description in that the flank angle β 75 is larger than the flank angle α 74. For example, values of between 1° and 25° are advantageous for the angle α 74, and values of between 10° and 90° are advantageous for the upper angle β 75.

At this point, with respect to the process technology, it is to be noted that the above definition of the flank angles may represent an idealization when manufacturing such structures, since the corresponding face may have a certain roughness in reality, for example. The transition from one curve (face) piece to the next may have irregularities and small deviations from the target shape. Applying tangents may be understood in this sense as averaging the actual curve points across a sufficiently small piece of the curve.

Thus, for example, embodiments include such structures that comprise a small step or ridge in the transition of the curve section 70a to the curve section 71b or in which the tip has roundings in the transition of the curve 71a to 71b.

Embodiments of the inventive solution may comprise different shapes of the beam guiding units, e.g. configured as two-stage conical structures. This may concern the base shape of the structural base, e.g., i.e. the sectional area of the beam guiding unit with the substrate, and the shape of the surface pieces, e.g., i.e. the sidewall structure (curved or straight) which they may consist of. Regardless of shaping, some or even all embodiments or variations may be based on the IPE principle and may therefore comprise a Schottky junction at least in the (possibly flattened) tip of the conical structure.

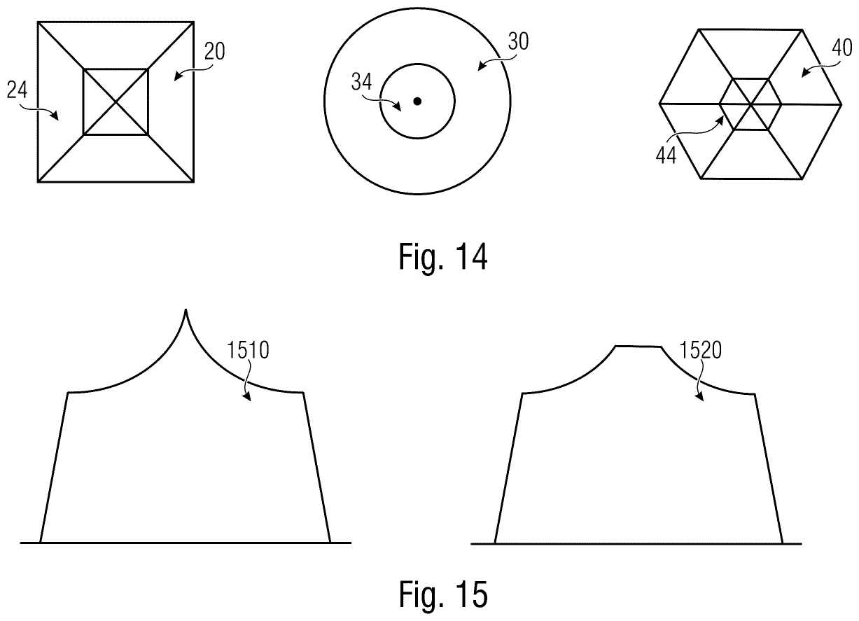

FIG. 14 shows three possible shapes of the structural base in a top view. In other words, FIG. 14 shows schematic top views of beam guiding units according to the present invention. A two-stage four-sided pyramid is created out of a square base 20. A circular base 30 results in a two-stage cone. The third example shows a hexagonal base 40 from which a two-stage hexagonal pyramid is created.

FIG. 15 shows two possible implementations in a cross-section perpendicular to the substrate surface. In other words, FIG. 15 shows schematic side views of two beam guiding units according to embodiments of the invention. The first structure 1510 consists of four curve sections in which the lower area, e.g., i.e. the first portion of the beam guiding unit, has a straight edge and the upper area, e.g., i.e. the second portion of the beam guiding unit, has a curved edge with a tip. In addition, the second implementation 1520 has a fifth curve section (small compared to the remaining structural side) in the upper area, through which the conical structure has a flat end. In other words, the beam guiding unit 1520 has a flattened tip. The second implementation may have advantages with respect to the process technology.

In order to realize the beam guiding units, e.g. configured as conical structures, according to embodiments, different semiconductor materials may be used. Beside silicon, germanium, or an alloy made of silicon and germanium may be used.

Furthermore, the semiconductor may comprise an n- or p-doping, which is why electrons or holes are the majority charge carriers of the apparatus, e.g. configured as a diode. The doping may be configured to be homogenous or gradual towards the interface.

The Schottky junction may be achieved by covering the semiconductor with a metal material, e.g. including a metal. For example, this may be aluminium, copper, nickel, gold or titanium. Furthermore, silicide's, such as nickel silicide (NiSi), cobalt silicide (CoSi), or titanium silicide (TiSi) may be used. A further possibility is the use of metallic nitride, such as titanium nitride (TIN). An essential requirement for the material on the metal side of the component may be a sufficient or good electrical conductivity. In addition to an individual metallic material, a layer stack of different materials, such as TiN/Al, may be used.

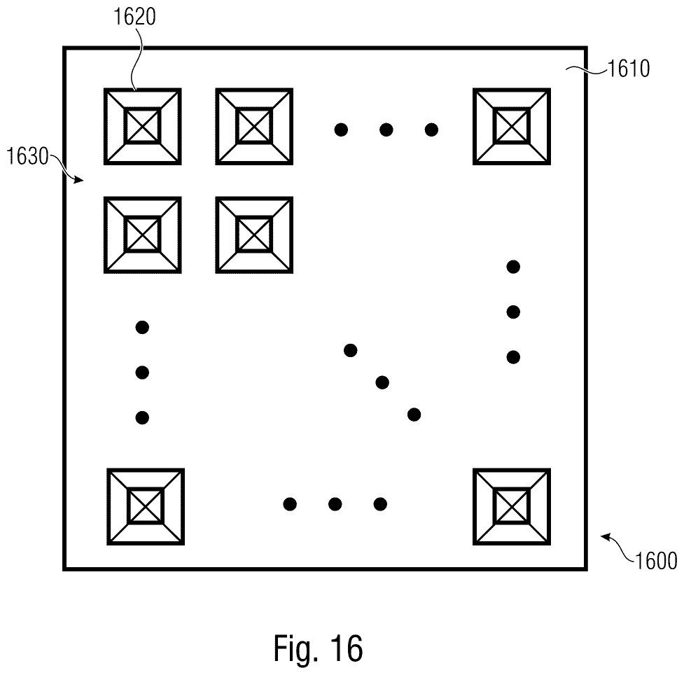

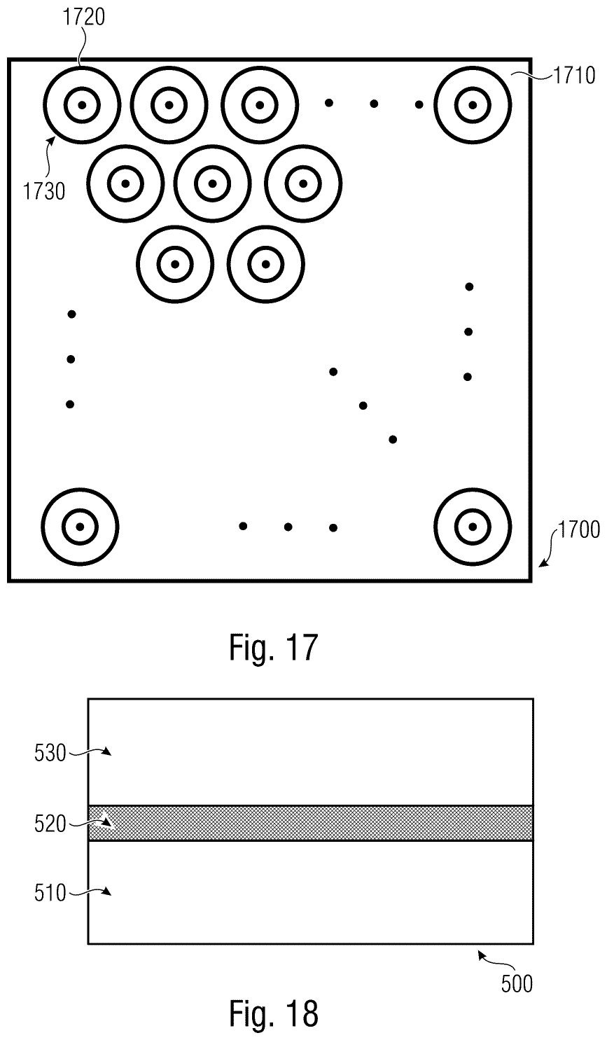

Furthermore, a system of inventive apparatuses, e.g. configured as a diode, may consist of several beam guiding units, e.g. in the form of conical structures, or include the same. They may be arranged in a grid. Different grids are possible, e.g. square or hexagonal. FIG. 16 shows a schematic top view of a system for absorbing electromagnetic radiation with a multitude of apparatuses with a square base area of the beam guiding unit, arranged in a square grid. FIG. 17 shows a schematic top view of a system for absorbing electromagnetic radiation with a multitude of apparatuses with a round base area of the beam guiding unit, arranged in a hexagonal grid. In other words, FIG. 16 shows an example of a square arrangement of square pyramidal structures in a diode, and FIG. 17 shows a hexagonal arrangement of cone structures. By combining several conical structures to a system, e.g. a diode, the sensitivity of the absorption apparatus, e.g. in the form of a diode, may be increased, since the effective total area is increased. The tips may be provided with a common metallization.

In other words, an inventive system 1600, 1700 for absorbing electromagnetic radiation may in general include a multitude of inventive apparatuses 1620, 1720, wherein the apparatuses are arranged in a grid 1630, 1640, wherein the substrates of the multitude of apparatuses form a common substrate 1610, 1710. Optionally, the system 1600, 1700 may be configured as a diode or image sensor, for example. For example, the system 1600, 1700 may have a focal plane array (FPA) or may be configured as such. FPAs may include image sensors or may be configured as such in applications in the infrared range. In other words, image sensors in the infrared range may be referred to as FPA, even though they are image sensors according to their function. As described in the context of FIGS. 16 and 17, inventive apparatuses and their beam guiding units may be arranged in any grid shape, such as a rectangular, square or hexagonal grid.

As described above, an effort for contacting may be simplified, e.g., by metal materials of the multitude of apparatuses 1620, 1720 comprising a first common contacting and/or wherein the common substrate 1610, 1710 comprises a second common contacting.

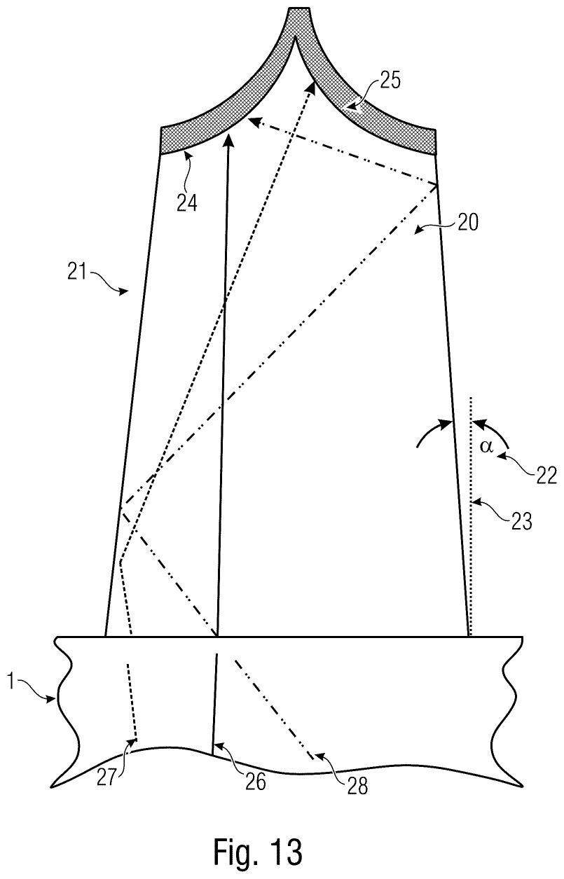

A variation of an inventive apparatus, e.g. as a conical photodiode, is illustrated in FIG. 13 as a schematic side view. FIG. 13 shows a schematic cross-section through a square conical structure 20 in which the lower area has at its edge straight lines 21 and the upper area has at its edge curve sections 24. Due to the steeper flank angle α 22, the three light beams 26, 27, 28 exemplarily shown reach the metal material, for example a metallization 25 of the structure, even after several reflections. This shows the significant advantage compared to the prior art in FIG. 9.

In this case, it is also to be noted that the metal material as shown in FIG. 13 may cover the entire surface, opposite the main side of substrate 1, of the beam guiding unit in general, or, as exemplarily shown in FIG. 1, only part thereof, e.g. an area around the tip of the second portion.

In principle, as exemplarily described on the basis of FIGS. 4a and 4b, the inventive solution may also be configured such that the two contacts for electrically contacting the apparatus, e.g. configured as a photodiode, are not arranged on the front side of the substrate, as illustrated in FIG. 6, but one contact is located on the substrate rear side (rear side contacting of the semiconductor).

The economic advantages of the silicon technology and the sustainability aspect by omitting heavy metals such are arsenic and lead may be highlighted as fundamental advantages over the prior art.

FIG. 18 shows a schematic side view of an SOI substrate according to embodiments of the present invention.

A so-called SOI (silicon-on-insulator) substrate 500 may also be used as a substrate for the inventive apparatuses, e.g. configured as conical photodiodes. For example, the substrate may consist of three layers. The first layer 510 may consist of a semiconductor material and is referred to as a carrier layer. It may promote mechanical stability in the processing, e.g. with a thickness of 100 μm. The second layer 520 may consist of an insulator material and may be configured so as to be much thinner than the carrier layer 500, e.g. typically in the range of some 100 nm or a few micrometers. In turn, the third layer 530 may be made of a semiconductor material and may vary in its thickness depending on the application. The semiconductor technology almost exclusively uses the material combination of silicon-silicon dioxide-silicon.

The electronically functional device may be created in the third layer 530 which may be adjusted with respect to its characteristics (e.g. doping), or in other words, it may be generated in the course of an inventive manufacturing method.

For embodiments according to the present invention, the advantage of using such substrates may be the possibility to be able to selectively remove the carrier layer 510 (e.g. by wet-chemical etching) in the functional layer 530 with respect to the insulator layer 520, after having completed processing of the apparatuses, e.g. which may be configured as diodes. Through this, the light paths through the substrate may be substantially shortened.

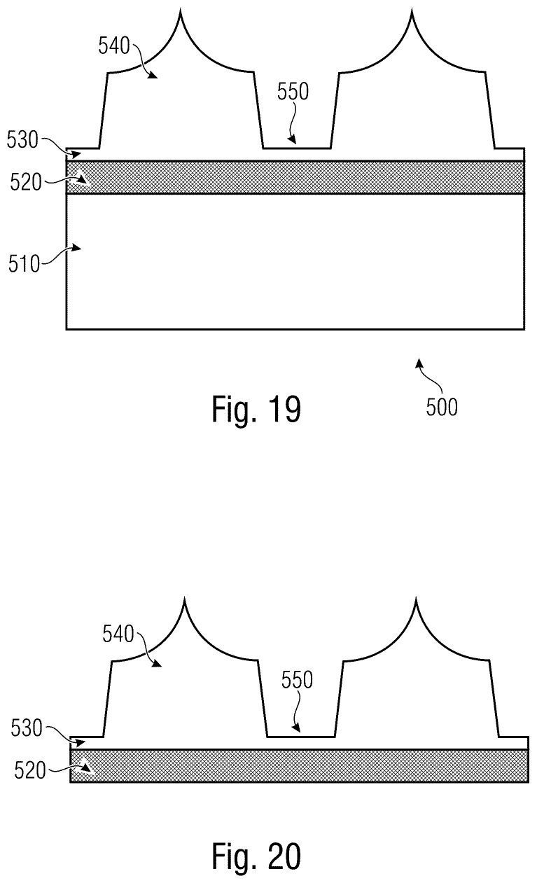

FIG. 19 shows a schematic side view of a multitude of apparatuses for absorbing electromagnetic radiation, said apparatuses being arranged on a common substrate, according to embodiments of the present invention. For example, FIG. 19 shows an intermediate product of a manufacturing process.

The light guiding units, exemplarily configured as conical structures 540 for the apparatuses, e.g. which may be photodiodes, may be structured into the third layer 530, e.g. by etching processes, e.g. by means of wet-chemical etching methods in two directly subsequent process steps using at least two parametrizations. If neighboring structures need a common electrical contact, a thin ridge 550 may remain between these structures. If this is not the case, the sidewall of the conical structure may also reach up to the second layer 520.

In other words, for example, arranging a beam guiding unit at the main side of the substrate may include processing the third layer 530 so that the beam guiding unit is arranged at the second layer 520 or at a remaining part of the third layer of the SOI substrate 500.

FIG. 20 shows a schematic side view of a multitude of apparatuses for absorbing electromagnetic radiation, arranged on a common substrate, with a carrier layer being removed, according to embodiments of the present invention.

Removing the carrier layer 510 may significantly shorten the light path through the substrate in case of an illumination from the rear side, for example. Through this, residual absorption in the substrate and possible crosstalk between different conical structures may be minimized.

In other words, methods according to embodiments of the present invention may have as a further optional feature: providing a carrier layer 510; and arranging an insulator layer 520 on the carrier layer; and arranging the semiconductor material 530s on the insulator layer and at least partially removing the carrier layer after arranging the beam guiding unit 540.

In general, methods according to embodiments of the present invention may further include arranging a plurality of beam guiding units 540 on the main side of the substrate and arranging the metal material at the second portions of the beam guiding units (not shown) on a side of the second portions facing away from the substrate; wherein arranging the plurality of beam guiding units includes partially removing the semiconductor material in an area 550 between at least two neighboring beam guiding units, and arranging a common contacting (not shown) of the at least two neighboring beam guiding units in the area 550 of the partially removed semiconductor material.

Furthermore, with respect to FIGS. 18 to 20, it is to be noted that the SOI substrate 500 may form the substrate of the inventive apparatus. For example, as shown in FIG. 19, if part of the semiconductor layer 530 is “left standing” below the semiconductor material structured as the beam guiding units 540, an inventive substrate may be formed by an SOI substrate. For example, in such a case, the layer 510 may only be thinned and not fully removed. Alternatively, the substrate of the apparatus may also be formed only by the insulator layer 520 of the SOI arrangement 500, e.g. if the beam guiding units are etched out of the layer 530, “down” to the insulator layer 520. For example, in this case, the layer 510 may also be fully removed so that the substrate is formed below the beam guiding units only by the layer 520. According to the invention, however, combinations of the layers and combinations of partially removed layers of the SOI substrate are also possible as a substrate for the beam guiding units. In addition, according to embodiments, mechanical stabilization of the system may also be carried out in case of a fully removed carrier layer 510 by coating the, e.g. fully processed, apparatuses, e.g. configured as diodes, on the front side with different materials of different thicknesses. In other words, the apparatus may be coated with one or several materials of different thicknesses from the side of the beam guiding units 540 (e.g. in case of already deposited metal material, e.g. in the form of a metallization). For example, this may have advantages if the layer 520, e.g. in the form of an SiO₂ layer, is configured to be very thin, and therefore does not have sufficient mechanical stiffness or stability. In other words, a thin or even very thin SiO₂ layer, e.g. as an insulator layer 520, may not have sufficient mechanical stiffness so that further coatings are deposited for stabilization, for example. Depositing additional stabilizing coatings is only possible in case of a partially removed carrier layer 510 or, e.g., in applications with high requirements with respect to the mechanical stiffness in case of a non-removed carrier layer 510.

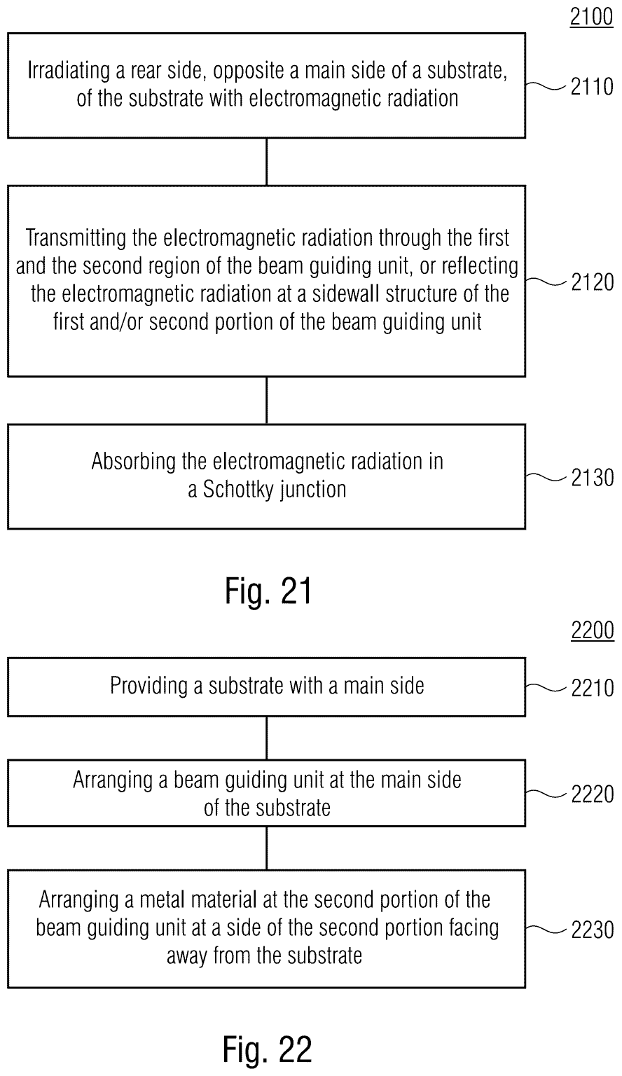

FIG. 21 shows a method for absorbing electromagnetic radiation according to embodiments of the present invention. FIG. 21 shows a method 2100 including irradiating 2110 a rear side, opposite the main side of a substrate, of the substrate with the electromagnetic radiation, wherein the substrate is transparent for the electromagnetic radiation so that the electromagnetic radiation enters into a beam guiding unit arranged on the main side of the substrate, and wherein the beam guiding unit comprises a semiconductor material, and wherein the semiconductor material is transparent for the electromagnetic radiation, and wherein the beam guiding unit comprises a first and a second portion, wherein the first portion is arranged facing the substrate and between the substrate and the second portion, and wherein a cross-sectional area of the beam guiding unit in parallel to the main side of the substrate decreases with an increasing distance to the main side more strongly in the second portion than in the first portion. The method further includes a step 2120 of transmitting the electromagnetic radiation through the first and second area of the beam guiding unit, or reflecting the electromagnetic radiation at a sidewall structure of the first and/or second portion of the beam guiding unit. In addition, the method includes absorbing 2130 the electromagnetic radiation at a Schottky junction, wherein the Schottky junction is provided by a metal material together with the second portion, wherein the metal material is arranged at the second portion of the beam guiding unit on a side of the second portion facing away from the substrate.

FIG. 22 shows a method for manufacturing an apparatus for absorbing electromagnetic radiation according to embodiments of the present invention. The method 2200 includes providing 2210 a substrate with a main side, wherein the substrate is transparent for the electromagnetic radiation, and arranging 2220 a beam guiding unit on the main side of the substrate, wherein the beam guiding unit comprises a semiconductor material, and wherein the semiconductor material is transparent for the electromagnetic radiation, and wherein the beam guiding unit includes a first and a second portion, wherein the first portion is arranged facing the substrate and between the substrate and the second portion, and wherein a cross-sectional area of the beam guiding unit in parallel to the main side of the substrate decreases with an increasing distance to the main side more strongly in the second portion than in the first portion. Furthermore, the method includes arranging 2230 a metal material at the second portion of the beam guiding unit on a side of the second portion facing away from the substrate, wherein, together with the second portion, the metal material provides a Schottky junction configured for absorbing the electromagnetic radiation.

The step 2220 may further optionally include a dry-chemical and/or wet-chemical etching method. As a further optional feature, the step 2220 may further include arranging a semiconductor material on the substrate; and etching the semiconductor material with a dry-chemical etching method in two directly subsequent process steps by using at least two parametrizations. In this case, etching the semiconductor material may include etching the semiconductor material in a first process step with the dry-chemical etching method with a first parametrization for generating the first portion of the beam guiding unit, and etching the semiconductor material in a directly subsequent second process step with the dry-chemical etching method with a second parametrization for generating the second portion of the beam guiding unit.

In this case, the first and the second parametrizations of the dry-chemical etching method may be selected such that a cross-sectional area of the beam guiding unit in parallel to the main side of the substrate decreases with an increasing distance to the main side more strongly in the second portion than in the first portion.

For example, the great advantage of embodiments according to the present invention over the prior art is the use of silicon as a semiconductor, as this may allow utilizing the enormous economic advantages of the silicon technology. The inventive solution is not based on the otherwise conventional pin diode (since the same is mostly insensitive for silicon in NIR), but on the principle of internal photoemission at a Schottky junction between the silicon and a metal material.

### CONCLUSIONS AND FURTHER REMARKS

In the following, further embodiments of the invention are listed, and previously described embodiments are summarized in other words:
1. Diode for detecting electromagnetic radiation, including or consisting of
   a semiconductor substrate,
   at least one conical structure on a front side of the semiconductor substrate,
   an electrically conductive layer that at least partially covers the conical structure,
   wherein a Schottky barrier is formed between the electrically conductive layer and the semiconductor substrate in the conical structure,
   and wherein, if the conical structure is irradiated with electromagnetic radiation, electrical charge carriers are emitted out of the electrically conductive layer into the conical structure of the semiconductor substrate, and these charge carriers can be measured as a photocurrent.
2. Diode according to embodiment 1, comprising:
   a first contact located outside of the conical structure for electrically contacting the semiconductor substrate,
   a second contact for electrically contacting the electrically conductive layer, wherein the photocurrent is measured between the first and the second contact.
3. Diode according to the preceding embodiments, wherein the conical structure has, in a cross-sectional area in parallel to the front side of semiconductor substrate, a finite number of continuous curve sections as its edge.
4. Diode according to embodiments, wherein the continuous curve sections form a circle, or an ellipse, or a polygon.
5. Diode according to embodiments 3 and 4, wherein the conical structure has, in a cross-sectional area perpendicular to the front side of the semiconductor substrate, a finite number of continuous curve sections as its edge.
6. Diode according to claim 5, wherein an edge of the conical structure consists of four or five curve sections, dividing the conical structure into a lower area and an upper area, wherein the lower area is directly adjacent to the semiconductor substrate, and a flank angle between a tangent of the associated curve section and a surface normal of the front side is smaller than a flank angle between a tangent of the curve section of the upper area and a surface normal of the front side.
7. Diode according to embodiment 6, wherein the flank angle of the curve section for the lower area is between 1° and 25°, and the flank angle of the curve section for the upper area is between 5° and 90°.
8. A diode according to embodiments 6 and 7, wherein the curve section for the lower area of the conical structure is a straight line, and the curve section for the upper area is an arch piece.
9. Diode according to embodiments 6 and 7, wherein the curve section for the lower area of the conical structure is a straight line and the curve section for the upper area is a straight line.
10. Diode according to any of the preceding claims, wherein the semiconductor substrate consists of silicon, or germanium, or an alloy of silicon and germanium.
11. Diode according any to the preceding embodiments, wherein the conical structure is created by structuring the front side of the semiconductor substrate.
12. Diode according any to the preceding claims, wherein the conical structure comprises an n-doping or p-doping.
13. Diode according to embodiment 12, wherein the doping is configured to be homogenous or gradual.
14. Diode according any to the preceding embodiments, wherein the electrically conductive layer at least partially covering the conical structure is made of a metal, or a silicide, or a germanide, or a metallic nitride.
15. Diode according any to the preceding claims, wherein the conical structure comprises a height between 0.5 μm and 25 μm.
16. Diode according any to the preceding embodiments, wherein at least a part of the electromagnetic radiation in the conical structure is focused in the conical structure.
17. Diode according any to the preceding embodiments, wherein plasmonic effects occur in an area of the tip of the conical structure in the electrically conductive layer and increase a sensitivity of the diode.
18. Diode according any to the preceding embodiments, wherein the electromagnetic radiation that leads to an emission of charge carriers out of the electrically conductive layer is a wavelength range of between 1000 nm and 3000 nm.
19. Diode according any to the preceding embodiments, consisting of several conical structures.
20. Diode according any to embodiment 19, wherein the conical structures are arranged in a regular grid.
21. Diode according to embodiment 20, wherein the grid is square, rectangular, or hexagonal.
22. Diode according any to the preceding embodiments, wherein the irradiation of the conical structure takes place from a rear side of the substrate.

All materials, environmental influences, electrical characteristics, and optical characteristics described herein are considered to be examples and are not exhaustive.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

[1] Casamino et. al., Opt. Express 20, 12599 (2012)
[2] B. Desiatov et al., “Plasmonic enhanced silicon pyramids for internal photoemission Schottky detectors in the near-infrared regime”, Optica, Jg. 2, no. 4, page 335, 2015, doi: 10.1364/OPTICA.2.000335.
[3] U.S. Pat. No. 5,285,098A
[4] Sebastian R. Borrello, “STRUCTURE AND METHOD INTERNAL PHOTOEMISSION,” US5285098A. U.S. Pat. No. 877,433, Feb. 8, 1994.
[5] B. Feng et al., “All-Si Photodetectors with a Resonant Cavity for Near-Infrared Polarimetric Detection” (eng), Nanoscale research letters, Jg. 14, Nr. 1, S. 39, 2019, doi: 10.1186/s11671-019-2868-3.
[6] J. Duran und A. Sarangan, “Schottky-Barrier Photodiode Internal Quantum Efficiency Dependence on Nickel Silicide Film Thickness”, IEEE Photonics J., Jg. 11, no. 1, pages 1-15, 2019, doi: 10.1109/JPHOT.2018.2886556.
[7] Edward P. Smith, Anne Itsuno, Justin Gordon Adams Wehner, “PHOTODETECTOR HAVING PLASMONIC RESONANCE AND PHOTON CRYSTAL THERMAL NOISE SUPPRESSION,” US20150221796A1. U.S. Ser. No. 14/174,172, Aug. 6, 2015.
[8] Z. Wang, X. Wang und J. Liu, “Nanophotonic hot-electron devices for infrared light detection,” WO 2019/018039 A2. US PCT/US2018/028688, Jan. 24, 2019.
[9] H.-L. Chen, K.-T. Lin, Y.-S. Lai und C.-C. Yu, “Photodetector and method of fabricating the same,” US 2015/0228837 A1. TW 14/616,890, Aug. 13, 2015.
[10] Z. Zhang, X. Han und K. He, “Perfect Absorber,” WO 2018/176270 A1. CN PCT/CN2017/078603, Oct. 4, 2018.
[11] JACEK GOSCINIAK, “WAVEGUIDE INTEGRATED PLASMONIC SCHOTTKY PHOTODETECTOR,” US2020/0144437A1. United States 161539,029, May 7, 2020.

1. An apparatus for absorbing electromagnetic radiation, the apparatus comprising:
a substrate with a main side,
wherein the substrate is transparent for the electromagnetic radiation; and
a beam guiding unit arranged on the main side of the substrate,
wherein the beam guiding unit comprises a semiconductor material and wherein the semiconductor material is transparent for the electromagnetic radiation, and
wherein the beam guiding unit comprises a first and a second portion, wherein the first portion is arranged facing the substrate and between the substrate and the second portion, and
wherein a cross-sectional area of the beam guiding unit in parallel to the main side of the substrate decreases with an increasing distance to the main side more strongly in the second portion than in the first portion; and
a metal material,
wherein the metal material is arranged at the second portion of the beam guiding unit on a side of the second portion facing away from the substrate, and
wherein the metal material provides together with the second portion a Schottky junction configured for absorbing the electromagnetic radiation.

2. The apparatus according to claim 1, wherein the first portion of the beam guiding unit comprises a first sidewall structure that, starting from the substrate, is inclined with a first inclination angle with respect to a surface normal of the main side so that the first portion tapers starting from the substrate so as to focus the electromagnetic radiation received by the substrate.

3. The apparats according to claim 2, wherein the second portion comprises a second sidewall structure that, starting from the first portion, is inclined with a second inclination angle with respect to a surface normal of the main side, and
wherein the second inclination angle is larger than the first inclination angle so that the second portion tapers starting from the first portion.

4. The apparatus according to claim 3, wherein the second portion with the second sidewall structure is configured to focus the electromagnetic radiation received by the substrate and/or to facilitate absorption of the electromagnetic radiation in the Schottky junction by means of plasmonic effects.

5. The apparatus according to claim 3,
wherein the first inclination angle is at least 1° and at most 25°, or wherein the first inclination angle is less than 10°, and/or
wherein the second inclination angle is at least 10° and at most 90°.

6. The apparatus according to claim 3,
wherein the first inclination angle is an angle between a tangent of the first sidewall structure and the surface normal at the transition between the first and the second portion of the beam guiding unit, and/or
wherein the second inclination angle is an angle between a tangent of the second sidewall structure and the surface normal at the transition between the first and the second portion of the beam guiding unit; or
wherein the first inclination angle is an angle between a secant of the first sidewall structure and the surface normal, wherein the secant is determined by two points that overlap vertically, with respect to the main side of the substrate, on the first sidewall structure, wherein a first point of the two points is located in a sectional line between the first sidewall structure and the main side of the substrate, and wherein a second of the two points is located in a sectional line between a first and a second portion of the beam guiding unit, and/or
wherein the second inclination angle is an angle between a secant of the second sidewall structure and surface normal, wherein the secant is determined by two points that overlap vertically, with respect to the main side of the substrate, on the second sidewall structure, wherein a first point of the two points is located in a sectional line between the first and the second portion of the beam guiding unit, and wherein a second of the two points forms a point of the second portion with the largest vertical distance to the main side of the substrate.

7. The apparatus according to claim 1, wherein the Schottky junction is adjusted to a wavelength range, and wherein a width of an interface between the first and the second portion of the beam guiding unit projected onto the base area of the beam guiding unit is at least 0.2 times a wavelength of the wavelength range and at most 15 times a wavelength of the wavelength range, wherein the base area of the beam guiding unit is a sectional area of the beam guiding unit with the substrate.

8. The apparatus according to claim 3, wherein the first and/or the second sidewall structure is configured to be straight or curved.

9. The apparatus according to claim 1, wherein the second point of the beam guiding unit comprises, on a side facing away from the substrate, a tip or a flattened tip, and wherein the metal material is arranged only in the area of this tip or flattened tip.

10. The apparatus according to claim 9, wherein the Schottky junction is adapted to a wavelength range, and
wherein the second portion comprises a flattened tip, and
wherein a flattened area of the tip comprises a width, in parallel to the main side of the substrate, that is smaller than a smallest wavelength of the wavelength range or that corresponds to the smallest wavelength of the wavelength range.

11. The apparatus according to claim 10, wherein the tip or the flattened tip of the beam guiding unit is configured to cause and/or amplify a plasmonic effect in the metal material deposited in the area of the tip.

12. The apparatus according to claim 1,
wherein the substrate comprises a layer stack; and/or
wherein the semiconductor material of the beam guiding unit comprises silicon, germanium, and/or a material compound comprising silicon and/or germanium.

13. The apparatus according to claim 1,
wherein the metal material comprises a layer stack; and/or
wherein the metal material comprises a metal, a silicide, and/or a metallic nitride.

14. The apparatus according to claim 1,
wherein the metal material comprises at least one of aluminum, copper, nickel, gold, titanium, nickel silicide, cobalt silicide, titanium silicide and/or titanium nitride.

15. The apparatus according to claim 1,
wherein the semiconductor material of the beam guiding unit comprises a doping, and wherein a doping degree of the doping towards the Schottky junction is constant, stepped, or gradually variable.

16. The apparatus according to claim 1, wherein the beam guiding unit comprises an at least partially round, elliptical, or polygonal base area, wherein the base area of the beam guiding unit forms the sectional area of the beam guiding unit with the substrate.

17. The apparatus according to claim 1, wherein the beam guiding unit comprises a height, vertical to the main side of the substrate, of at least 0.5 μm and at most 25 μm.

18. The apparatus according to claim 1, wherein the apparatus is configured for absorbing electromagnetic radiation with a wavelength in the range of at least 1000 nm and at most 3000 nm or of at least 1000 nm and at most 1700 nm.

19. The apparatus according to claim 1, wherein the apparatus comprises a first and a second electrical contacting, and
wherein the first contacting is connected in an electrically conductive way to the metal material; and
wherein the second contacting is connected in an electrically conductive way to the semiconductor material; and
wherein the first and second contacting are configured to provide a photocurrent, on the basis of an internal photoemission, through electromagnetic radiation absorbed at the Schottky junction.

20. The apparatus according to claim 19, wherein the first and the second contacting are arranged at opposite sides of the apparatus; or
wherein the first and the second contacting are arranged on a same side of the apparatus.

21. A system for absorbing electromagnetic radiation, the system comprising a multitude of apparatuses according to claim 1,
wherein the apparatuses are arranged in a grid, and
wherein the substrates of the multitude of apparatuses form a common substrate.

22. The system according to claim 21, wherein the system is an image sensor and/or a focal plane array.

23. The system according to claim 21, wherein the multitude of apparatuses is arranged in a rectangular, square, hexagonal grid.

24. The system according to claim 21, wherein the metal materials of the multitude of apparatuses comprise a first common contacting and/or wherein the common substrate comprises a second common contacting.

25. A method for absorbing electromagnetic radiation, the method comprising
irradiating a rear side, opposite a main side of a substrate, of the substrate with the electromagnetic radiation,
wherein the substrate is transparent for the electromagnetic radiation, so that the electromagnetic radiation enters into a beam guiding unit arranged on the main side of the substrate, and
wherein the beam guiding unit comprises a semiconductor material, and wherein the semiconductor material is transparent for the electromagnetic radiation, and
wherein the beam guiding unit comprises a first and a second portion, wherein the first portion is arranged facing the substrate and between the substrate and the second portion, and
wherein a cross-sectional area of the beam guiding unit in parallel to the main side of the substrate decreases with an increasing distance to the main side more strongly in the second portion than in the first portion; and
transmitting the electromagnetic radiation through the first and the second area of the beam guiding unit, or reflecting the electromagnetic radiation at a sidewall structure of the first and/or second portion of the beam guiding unit; and
absorbing the electromagnetic radiation in a Schottky junction,
wherein the Schottky junction is provided by a metal material together with the second portion, wherein the metal material is arranged at the second portion of the beam guiding unit on a side of the second portion facing away from the substrate.

26. A method for manufacturing an apparatus for absorbing electromagnetic radiation, the method comprising:
providing a substrate with a main side,
wherein the substrate is transparent for electromagnetic radiation; and
arranging a beam guiding unit on the main side of the substrate,
wherein the beam guiding unit comprises a semiconductor material, and wherein the semiconductor material is transparent for the electromagnetic radiation, and
wherein the beam guiding unit comprises a first and a second portion, wherein the first portion is arranged facing the substrate and between the substrate and the portion, and
wherein a cross-sectional area of the beam guiding unit in parallel to the main side of the substrate decreases with an increasing distance to the main side more strongly in the second portion than in the first portion; and
arranging a metal material at the second portion of the beam guiding unit on a side of the second portion facing away from the substrate,
wherein, together with the second portion, the metal material provides a Schottky junction configured for absorbing the electromagnetic radiation.

27. The method according to claim 26, wherein arranging the beam guiding unit comprises a dry-chemical and/or a wet-chemical etching method.

28. The method according to claim 27, wherein arranging the beam guiding unit further comprises:
arranging a semiconductor material on the substrate; and
etching the semiconductor material with a dry-chemical etching method in two directly subsequent process steps by using at least two parametrizations, wherein etching the semiconductor material comprises:
etching the semiconductor material in a first process step with the dry-chemical etching method with a first parametrization for generating the first portion of the beam guiding unit, and
etching the semiconductor material in a subsequent second process step with the dry-chemical etching method with a second parametrization for generating the second portion of the beam guiding unit,
wherein the first and the second parametrization of the dry-chemical etching method are selected such that a cross-sectional area of the beam guiding unit in parallel to the main side of the substrate decreases with an increasing distance to the main side more strongly in the second portion than in the first portion.

29. The method according to claim 26, wherein the method further comprises:
providing a carrier layer, and
arranging an insulator layer on the carrier layer; and
arranging the semiconductor material on the insulator layer; and
at least partially removing the carrier layer after arranging the beam guiding unit.

30. The method according to claim 26, wherein the method further comprises:
arranging a plurality of beam guiding units on the main side of the substrate; and
arranging the metal material at the second portions of the beam guiding units on a side of the second portions facing away from the substrate;
wherein arranging the plurality of beam guiding units comprises partially removing the semiconductor material in an area between at least two neighboring beam guiding units; and
arranging a common contacting of the at least two neighboring beam guiding units in the area of the partially removed semiconductor material.
